(19) United States
(12) Patent Application Publication
(10) Pub. No.: US 2023/0221811 A1
(43) Pub. Date: Jul. 13, 2023

(54) ELECTRONIC DEVICE

(71) Applicant: SEMICONDUCTOR ENERGY LABORATORY CO., LTD., Atsugi-shi, Kanagawa-ken (JP)

(72) Inventors: Kazunori WATANABE, Machida, Tokyo (JP); Koji KUSUNOKI, Isehara, Kanagawa (JP); Naoto KUSUMOTO, Isehara, Kanagawa (JP); Kensuke YOSHIZUMI, Atsugi, Kanagawa (JP); Yoshiaki OIKAWA, Atsugi, Kanagawa (JP)

(21) Appl. No.: 18/008,623

(22) PCT Filed: Jun. 7, 2021
(86) PCT No.: PCT/IB2021/054948

§ 371 Date: Dec. 6, 2022

(30) Foreign Application Priority Data
Jun. 19, 2020 (JP) 2020-106069

(51) Int. Cl. G06F 3/0354; H10K 39/00

(52) U.S. Cl. CPC G06F 3/03542; H10K 39/601

(57) ABSTRACT

An electronic device having a noncontact input function is provided. The electronic device includes a display device and an input device and is capable of performing an input operation even without contact. The display device includes a light-emitting device and a light-receiving device in a display portion. The input device includes a light source. The light-receiving device has a function of detecting light emitted from the light source included in the input device. Infrared light that has substantially no spectral luminous efficacy is used as the light emitted from the light source included in the input device. Therefore, even irradiation of the display portion with the light at high luminance does not affect visual recognition of the display. This structure enables a noncontact input operation with respect to the display device.

### TECHNICAL FIELD

One embodiment of the present invention relates to an electronic device.

Note that one embodiment of the present invention is not limited to the above technical field. Examples of the technical field of one embodiment of the present invention include a semiconductor device, a display device, a light-emitting apparatus, a power storage device, a memory device, a lighting device, an input device (e.g., a touch sensor or the like), an input/output device (e.g., a touch panel or the like), a driving method thereof, and a manufacturing method thereof.

Note that in this specification and the like, a semiconductor device generally means a device that can function by utilizing semiconductor characteristics. A transistor and a semiconductor circuit are embodiments of semiconductor devices. In addition, in some cases, a memory device, a display device, an imaging device, or an electronic device includes a semiconductor device.

### BACKGROUND ART

In recent years, display devices have been applied to a variety of uses. Examples of uses for large-size display devices include television devices for home use, digital signage, and PIDs (Public Information Display). Furthermore, examples of uses for small- and medium-size display devices include portable information terminals such as smartphones and tablet terminals.

Light-emitting apparatuses including light-emitting devices have been developed as display devices, for example. Light-emitting devices utilizing an electroluminescence (hereinafter referred to as EL) phenomenon have features such as thinness and lightweight, high-speed response, and capability of low-voltage driving. Patent Document 1, for example, discloses a flexible light-emitting apparatus.

### REFERENCE

### Patent Document

[Patent Document 1] Japanese Published Patent Application No. 2014-197522

### SUMMARY OF THE INVENTION

### Problems to be Solved by the Invention

Since electronic devices including display devices are used for a variety of uses as described above, the electronic devices are desired to have high functionality. For example, a more convenient electronic device can be achieved with a user interface function, an imaging function, or the like. An input function of a touch panel or the like is used as a user interface in many cases. A touch panel has a useful function, that is, the touch panel can be operated with part of a body such as a finger touching a panel surface. On the other hand, in the case where the panel is located in a position where one cannot physically touch, the panel cannot be operated. In addition, a touch panel has a problem of insufficient hygiene control of a panel surface (e.g., attachment or the like of dust, bacteria, or viruses).

In view of the above, an object of one embodiment of the present invention is to provide an electronic device having a noncontact input function. Another object is to provide an electronic device having a function of detecting light. Another object is to provide a novel electronic device. Another object is to provide a novel semiconductor device or the like.

Note that the description of these objects does not preclude the existence of other objects. Note that in one embodiment of the present invention, there is no need to achieve all the objects. Note that other objects will be apparent from the description of the specification, the drawings, the claims, and the like, and other objects can be derived from the description of the specification, the drawings, the claims, and the like.

### Means for Solving the Problems

One embodiment of the present invention is an electronic device that includes a display device including a light-emitting device and a light-receiving device in a display portion and an input device including a light-emitting device.

One embodiment of the present invention is an electronic device that includes a display device and an input device. The display device includes a light-emitting device and a light-receiving device in a display portion. The input device includes a light source. The display device performs display through light emission from the light-emitting device. When light emitted from the light source is detected by the light-receiving device, the display is changed.

Another embodiment of the present invention is an electronic device that includes a display device and an input device. The display device includes a light-emitting device, a light-receiving device, and a first communication circuit. The input device includes a light source and a second communication circuit. The display device performs display through light emission from the light-emitting device. When the input device is in a state of being authenticated by the display device through the second communication circuit and the first communication circuit and light emitted from the light source is detected by the light-receiving device, the display is changed.

The light-emitting device can have a function of emitting visible light. The light-receiving device can have a function of detecting infrared light. The light source can have a function of emitting infrared light.

It is preferable that the light-emitting device have a function of emitting light of any of red, green, blue, and white.

It is preferable that the light-receiving device include a photoelectric conversion layer and include an organic compound in the photoelectric conversion layer.

The light-emitting device and the light-receiving device can each have a structure of a diode, and a cathode of the light-emitting device and an anode of the light-receiving device can be electrically connected to each other. Alternatively, the cathode of the light-emitting device and a cathode of the light-receiving device can be electrically connected to each other.

It is preferable that a visible-light cut-off filter be provided in a position overlapping the light-receiving device.

The light-receiving device is capable of detecting light emitted from a position where the input device is not in contact with the display device.

It is preferable that the light source be a laser.

It is preferable that the light-emitting device and the light-receiving device be electrically connected to a plurality of transistors, each of the transistors include a metal oxide in a channel formation region, and the metal oxide include In, Zn, and M (M is Al, Ti, Ga, Ge, Sn, Y, Zr, La, Ce, Nd, or Hf).

### Effect of the Invention

According to one embodiment of the present invention, a display device having a noncontact input function can be provided. Alternatively, a display device having a function of detecting light can be provided. Alternatively, a novel display device can be provided. Alternatively, a novel semiconductor device or the like can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a diagram illustrating an electronic device.

FIG. 2A to FIG. 2C are diagrams illustrating the electronic device.

FIG. 3 is a diagram illustrating a display device.

FIG. 4A to FIG. 4E are diagrams illustrating pixel structures.

FIG. 5 is a cross-sectional view illustrating a display device.

FIG. 6A to FIG. 6C are cross-sectional views illustrating display devices.

FIG. 7A and FIG. 7B are cross-sectional views illustrating display devices.

FIG. 8A and FIG. 8B are cross-sectional views illustrating display devices.

FIG. 9A and FIG. 9B are cross-sectional views illustrating display devices.

FIG. 10 is a perspective view illustrating a display device.

FIG. 11 is a cross-sectional view illustrating a display device.

FIG. 12A and FIG. 12B are cross-sectional views illustrating a display device.

FIG. 13A and FIG. 13B are cross-sectional views illustrating a display device.

FIG. 14 is a cross-sectional view illustrating a display device.

FIG. 15A to FIG. 15D are diagrams illustrating pixel circuits.

FIG. 16 is a diagram illustrating a pixel circuit.

FIG. 17 is a diagram illustrating a pixel circuit.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are divided and arranged in a plurality of positions.

In addition, one conductor has a plurality of functions such as a wiring, an electrode, and a terminal in some cases. In this specification, a plurality of names are used for the same component in some cases. Furthermore, even in the case where elements are illustrated in a circuit diagram as if they were directly connected to each other, the elements may actually be connected to each other through one or more conductors. In this specification, even such a structure is included in the category of direct connection.

### (Embodiment 1)

In this embodiment, display devices according to embodiments of the present invention will be described.

One embodiment of the present invention is an electronic device that includes a display device and an input device and is capable of performing an input operation even without contact. The display device includes a light-emitting device (also referred to as a light-emitting element) and a light-receiving device (also referred to as a light-receiving device) in a display portion. The input device includes a light source.

The light-emitting device has a function of performing display. The light-receiving device has a function of detecting light emitted from the light source included in the input device.

Infrared light that has substantially no spectral luminous efficacy is used as the light emitted from the light source included in the input device. Therefore, even irradiation of the display portion with the light at high luminance does not affect visual recognition of the display. In addition, when the light is emitted at high luminance, the light can be detected with high sensitivity even in the case where the input device is positioned away from the display device. This structure enables a noncontact input operation with respect to the display device.

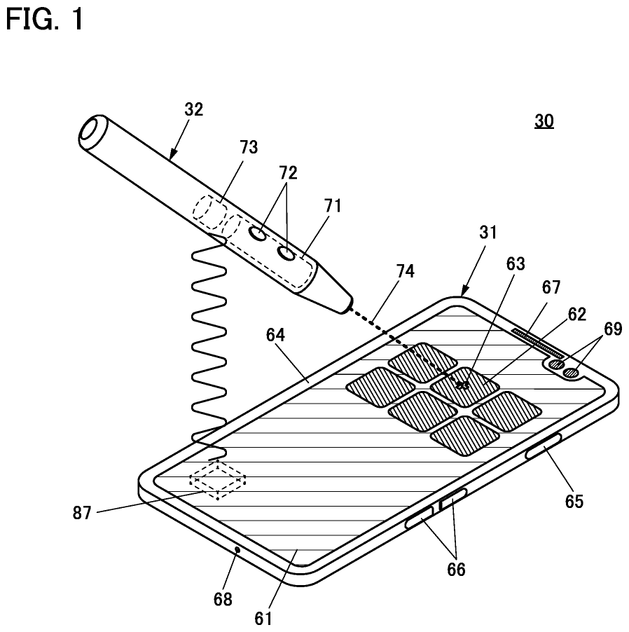

FIG. 1 is a diagram illustrating an electronic device 30 according to one embodiment of the present invention. The electronic device 30 includes a display device 31 and an input device 32.

The functions of the display device 31 are not particularly limited. Examples of the display device 31 include a digital camera, a digital video camera, a digital photo frame, a smartphone, a portable game machine, a portable information terminal, and an audio reproducing device, in addition to electronic devices with a comparatively large screen, such as a television device, a desktop or laptop computer, a tablet computer, a monitor of a computer or the like, digital signage, and a large-size game machine such as a pachinko machine.

The display device 31 may include a sensor (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, vibration, odor, or infrared rays).

The display device 31 can have a variety of functions. For example, the display device 31 can have a function of displaying a variety of information (a still image, a moving image, a text image, and the like) on a display portion, a function of displaying a calendar, date, time, and the like, a function of executing a variety of software (programs), a wireless communication function, and a function of reading a program or data stored in a recording medium.

FIG. 1 illustrates a smartphone as an example of the display device 31, and illustrates an example in which icons 62 are displayed on a display portion 61. In addition, the display device 31 includes a housing 64, a power button 65, buttons 66, a speaker 67, a microphone 68, a camera 69, and the like. The display portion 61 has a function of receiving light. Note that although FIG. 1 illustrates the example in which a plurality of buttons 66 and a plurality of buttons 72 are provided, one embodiment of the present invention is not limited thereto. For example, a structure may be employed in which one button 66 and one button 72 are provided.

The input device 32 has a function of irradiating the display portion 61 of the display device 31 with light 74. The input device 32 includes a light source 71 and can emit the light 74 by operating the button 72. In addition, an operation such as swiping or tapping on a touch panel can also be performed by an operation of moving an irradiation position while the button 72 is being pushed, an operation of pushing the button 72 a specified number of times, or the like. In other words, display on the display portion 61 can be changed by irradiation of the display portion 61 with the light 74.

Examples of changing display include an operation such as switching an image displayed on the display portion 61 or setting a display panel in an off state, for example, an operation of starting a program, an operation of scrolling a screen, an operation of projecting a picture or a video on the display portion, or an operation of temporarily setting the display portion 61 in an unlighted state by the operation of pushing the button 72.

In order to perform the above operation in the display device 31 by the operation of pushing the button 72, a signal component is added to the light 74 emitted from the input device 32. For example, the above operation can be performed by assigning a pulse signal to the above operation, transmitting the signal to the display device 31 by using the light 74, and receiving the signal by the display device 31.

It is preferable that light with high directivity can be emitted from the light source 71, and it is preferable to use a laser or a light-emitting diode as the light source 71. In addition, it is preferable that the light source 71 emit infrared light. Infrared light is nonvisible light and does not affect display visibility even when illuminance is high.

Although near-infrared light to far-infrared light can be used as infrared light, a heat source or the like becomes noise in far-infrared light; thus, near-infrared light that is light with a peak (wavelength of 720 to 2500 nm) is preferably used. As a semiconductor that is used for a laser emitting near-infrared light or a light-emitting layer of a light-emitting diode, GaAs, GaAlAs, InGaAs, or the like can be used, for example.

When the display portion 61 is irradiated with the light 74 emitted from the input device 32, the display device 31 displays a pointer 63 on the irradiated portion of the display portion 61. When the pointer 63 appears on the display portion 61, the irradiation position of the light 74 with respect to the display portion 61 can be visually identified even when the light 74 is nonvisible light, and selection of the icon 62, or the like can be easily performed.

Furthermore, as a security measure, it is preferable that the input device 32 include a communication circuit 73, the display device 31 include a communication circuit 87, and input be possible only in a state where both of them are paired according to a communications standard such as bluetooth (registered trademark). Alternatively, a personal authentication function such as fingerprint authentication may be provided to the housing, the button 72, or the like of the input device 32 so that an operation of accepting the input of only an individual allowed by the display device side may be performed.

As described above, the electronic device according to one embodiment of the present invention performs an operation corresponding to the touch operation of the touch panel by using light, and thus a noncontact operation is possible. Consequently, even in the case where the display device 31 is in an inaccessible location, the display device 31 can be operated using the input device 32. In addition, part of a body such as a finger does not need to directly touch the display portion 61 or the like; thus, the electronic device can be utilized in a sanitary manner.

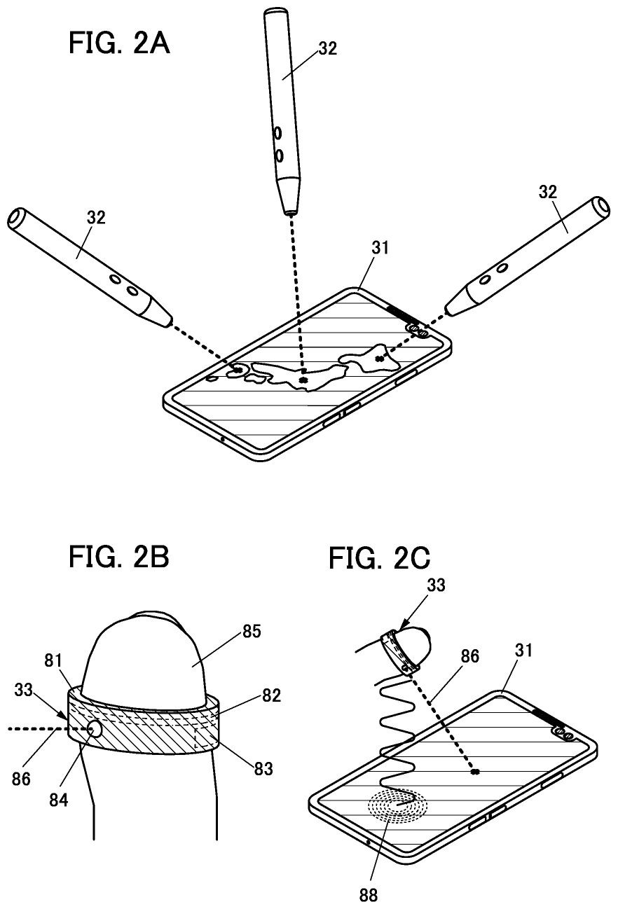

FIG. 2A is a diagram showing a situation where a plurality of input operations are performed at the same time using a plurality of input devices 32 for the display device 31. In this manner, a plurality of input devices 32 is adaptable to one display device 31. Alternatively, one input device 32 may be adaptable to a plurality of display devices 31.

FIG. 2B is a diagram showing an input device 33 that is in a mode different from the input device 32. The input device 33 includes a ring-like housing 81 and a light source 84 and can be mounted on a finger 85. Note that the housing 81 is not limited to having a ring-like shape, and may have a belt-like shape, a sac-like shape (a glove-like shape), or a cap-like shape.

Alternatively, although FIG. 2B illustrates an example in which the input device 32 is mounted on the vicinity of a fingertip, the input device 32 may be mounted on the vicinity of the base of the finger like a ring. Alternatively, the input device 32 may be mounted on a body part such as a palm, the back of a hand, a wrist, a neck, a head, a torso, a chest, the bottom of a foot, an instep, or an ankle. Alternatively, the input device 32 may be mounted on a toe, without being limited to the finger. The input device 32 may be mounted over clothes. The size and shape of the housing 81 can be determined as appropriate depending on a body part for mounting.

Note that the position of the light source 84 to be attached to the housing 81 and a light emission direction are not limited. Although FIG. 2B illustrates an example in which light is emitted in a direction substantially perpendicular to a surface of a ball of the finger, the light source 84 may be provided so that light is emitted to a diagonally upward direction (an upper side of FIG. 2B corresponds to an upper direction).

An antenna 82 and a battery 83 are provided in the housing 81, and a radio wave that is transmitted from a power feeding coil 88 included in the display device 31 can be received by the antenna 82 so that the battery 83 electrically connected to the light source 84 can be charged, as illustrated in FIG. 2C. In other words, even when the battery 83 is not charged in advance, the battery 83 can be wirelessly charged while being used, so that the battery 83 can be immediately used. Note that a capacitor may be used as the battery 83.

It is preferable that light 86 emitted from the light source 84 be infrared light. In addition, it is preferable to use a light-emitting diode with low power consumption that emits infrared light as the light source 84. Alternatively, the light source 84 may be a combination of a light-emitting diode and a lens (a cannonball type light-emitting diode). Light from the light-emitting diode has lower directivity than laser light; thus, it is preferable to use the input device 33 at a short distance from the display device 31. Furthermore, the light source 84 can also be used while being in contact with the display portion 61. Moreover, when light is emitted perpendicular to the surface of the ball of the finger as illustrated in FIG. 2B, touch panel-like operations are possible.

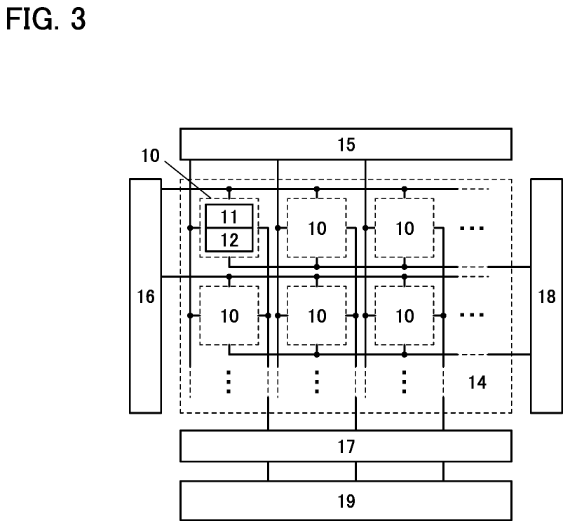

FIG. 3 illustrates a display panel included in a display device according to one embodiment of the present invention. The display panel includes a pixel array 14, a circuit 15, a circuit 16, a circuit 17, a circuit 18, and a circuit 19. The pixel array 14 includes pixels 10 arranged in a column direction and a row direction.

The pixel 10 can include subpixels 11 and 12. For example, the subpixel 11 has a function of emitting light for display. The subpixel 12 has a function of detecting light irradiated from the outside.

Note that in this specification, although the minimum unit in which an independent operation is performed in one “pixel” is defined as a “subpixel” in the description for convenience, a “pixel” may be replaced with a “region” and a “subpixel” may be replaced with a “pixel.”

The subpixel 11 includes a light-emitting device that emits visible light. As the light-emitting device, an EL element such as an OLED (Organic Light Emitting Diode) or a QLED (Quantum-dot Light Emitting Diode) is preferably used. As a light-emitting substance included in the EL element, a substance that emits fluorescence (a fluorescent material), a substance that emits phosphorescence (a phosphorescent material), a substance that exhibits thermally activated delayed fluorescence (a thermally activated delayed fluorescence (TADF) material), an inorganic compound (a quantum dot material or the like), and the like can be given. In addition, an LED (Light Emitting Diode) such as a micro-LED can be used as the light-emitting device.

The subpixel 12 includes a light-receiving device that has sensitivity to infrared light. Near-infrared light can be used as infrared light, for example. A photoelectric conversion element that detects incident light and generates electric charge can be used as the light-receiving device. In the light-receiving device, the amount of electric charge to be generated is determined on the basis of the amount of incident light. As the light-receiving device, a pn or a pin photodiode can be used, for example.

It is preferable to use an organic photodiode including an organic compound in a photoelectric conversion layer as the light-receiving device. An organic photodiode is easily made thin and lightweight and has a large area. In addition, an organic photodiode can be applied to a variety of display devices because of its high flexibility in shape and design. Alternatively, a photodiode using crystalline silicon (single crystal silicon, polycrystalline silicon, microcrystalline silicon, or the like) can be used as the light-receiving device.

In one embodiment of the present invention, an organic EL element is used as a first light-emitting device, and an organic photodiode is used as the light-receiving device. A large number of layers of the organic photodiode can be shared with the organic EL element. Accordingly, the light-receiving device can be incorporated into the display device without a significant increase in the number of manufacturing steps. For example, the photoelectric conversion layer of the light-receiving device and the light-emitting layer of the light-emitting device may be separately formed, and the other layers may have the same structure for the light-emitting device and the light-receiving device.

The circuit 15 and the circuit 16 are driver circuits for driving the subpixel 11. The circuit 15 can have a function of a source driver, and the circuit 16 can have a function of a gate driver. A shift register circuit or the like can be used as each of the circuit 15 and the circuit 16, for example.

The circuit 17 and the circuit 18 are driver circuits for driving the subpixel 12. The circuit 17 can have a function of a column driver, and the circuit 18 can have a function of a row driver. A shift register circuit, a decoder circuit, or the like can be used as each of the circuit 17 and the circuit 18, for example.

The circuit 19 is a read circuit for data output from the subpixel 12. The circuit 19 includes, for example, an A/D converter circuit and has a function of converting analog data output from the subpixel 12 into digital data. In addition, the circuit 19 may include a CDS circuit that performs correlated double sampling processing on output data.

The subpixel 12 can have a function of an input interface. The subpixel 12 can receive infrared light emitted from the outside of the display panel. Thus, when a threshold value of the amount of received infrared light detected by the subpixel 12 is set, a function of a switch can be obtained. These make it possible to achieve a function equivalent to a touch sensor without contact. In addition, an operation such as pointer movement can be performed without contact.

Furthermore, imaging data on a fingerprint, a palm print, an iris, or the like can be acquired using the light-receiving device. That is, a biological authentication function can be added to the display device. Note that imaging data may be acquired when an object is made to be in contact with the display device.

In addition, imaging data on facial expression, eye movement, a change of a pupil diameter, or the like of a user can be acquired using the light-receiving device. By analysis of the image data, information on the user's physical and mental state can be acquired. On the basis of the information, it is possible to perform an operation in accordance with the user's physical and mental state, e.g., to change one or both of display and sound output by the display device. Such operations are effective for devices for VR (Virtual Reality), devices for AR (Augmented Reality), or devices for MR (Mixed Reality).

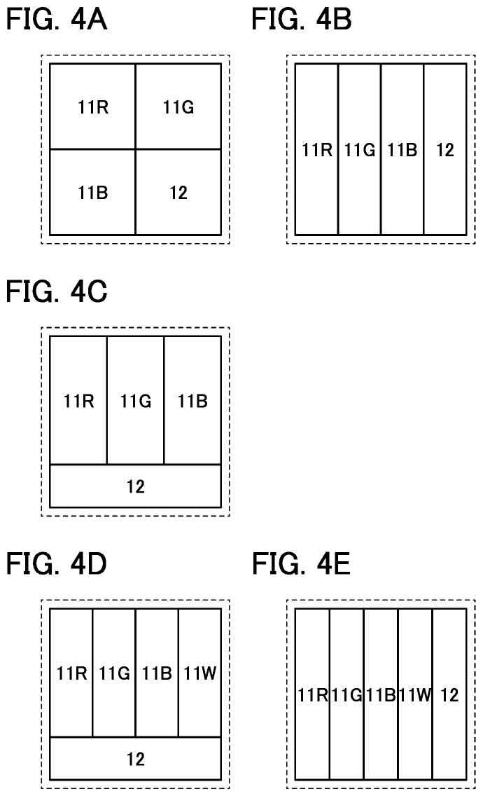

FIG. 4A to FIG. 4E are diagrams illustrating examples of the layout of the subpixels in the pixel 10. FIG. 3 illustrates the example in which one subpixel 11 and one subpixel 12 are placed in the pixel 10; however, as illustrated in FIG. 4A, a subpixel 11R including a light-emitting device that emits a red color, a subpixel 11G including a light-emitting device that emits a green color, and a subpixel 11B including a light-emitting device that emits a blue light may be placed in the pixel 10. Color display can be performed with this structure. Note that FIG. 4A illustrates layout in which the subpixel 11R, the subpixel 11G, the subpixel 11B, and the subpixel 12 are arranged vertically and horizontally; however, layout illustrated in FIG. 4B or FIG. 4C may be employed.

Furthermore, a subpixel 11W including a light-emitting device that emits a white color may be provided, as illustrated in FIG. 4D or FIG. 4E. Since the subpixel 11W can emit white light by itself, the emission luminance of subpixels of the other colors can be reduced in the case of display of a white color or a color close to a white color. Therefore, display can be performed with power saving.

Note that the structures of the pixels and the subpixels are not limited to the above, and a variety of arrangement modes can be employed.

Next, a more specific example of a display panel according to one embodiment of the present invention is described.

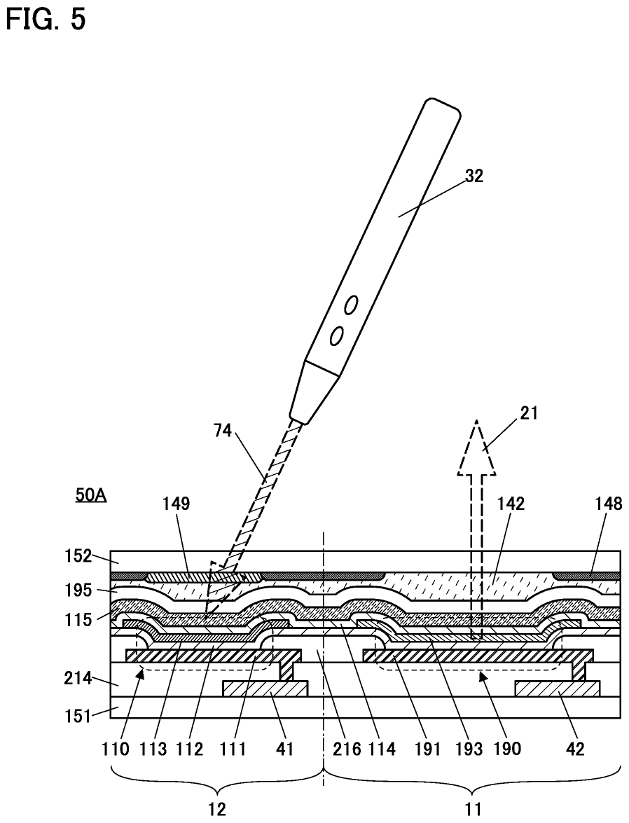

FIG. 5 is a cross-sectional schematic view illustrating a display panel 50A according to one embodiment of the present invention and a situation in which the display panel 50A is irradiated with the light 74 emitted from the input device 32. The display panel 50A includes a light-receiving device 110 and a light-emitting device 190. The light-receiving device 110 corresponds to the organic photodiode included in the subpixel 12. The light-emitting device 190 corresponds to the organic EL element (emitting visible light) included in the subpixel 11.

The light-receiving device 110 includes a pixel electrode 111, a common layer 112, a photoelectric conversion layer 113, a common layer 114, and a common electrode 115. The light-emitting device 190 includes a pixel electrode 191, the common layer 112, a light-emitting layer 193, the common layer 114, and the common electrode 115.

The pixel electrode 111, the pixel electrode 191, the common layer 112, the photoelectric conversion layer 113, the light-emitting layer 193, the common layer 114, and the common electrode 115 may each have either a single-layer structure or a stacked-layer structure.

The pixel electrode 111 and the pixel electrode 191 are positioned over an insulating layer 214. The pixel electrode 111 and the pixel electrode 191 can be formed using the same material in the same step.

The common layer 112 is positioned over the pixel electrode 111 and the pixel electrode 191. The common layer 112 is a layer shared by the light-receiving device 110 and the light-emitting device 190.

The photoelectric conversion layer 113 includes a region that overlaps the pixel electrode 111 with the common layer 112 therebetween. The light-emitting layer 193 includes a region that overlaps the pixel electrode 191 with the common layer 112 therebetween. The photoelectric conversion layer 113 includes a first organic compound. The light-emitting layer 193 includes a second organic compound different from the first organic compound.

The common layer 114 is positioned over the common layer 112, over the photoelectric conversion layer 113, and over the light-emitting layer 193. The common layer 114 is a layer shared by the light-receiving device 110 and the light-emitting device 190.

The common electrode 115 includes a region that overlaps the pixel electrode 111 with the common layer 112, the photoelectric conversion layer 113, and the common layer 114 therebetween. The common electrode 115 further includes a region that overlaps the pixel electrode 191 with the common layer 112, the light-emitting layer 193, and the common layer 114 therebetween. The common electrode 115 is a layer shared by the light-receiving device 110 and the light-emitting device 190.

In the display panel of this embodiment, an organic compound is used for the photoelectric conversion layer 113 of the light-receiving device 110. The light-receiving device 110 can have such a structure that the layers other than the photoelectric conversion layer 113 are shared with the light-emitting device 190 (the EL element). Therefore, the light-receiving device 110 can be formed concurrently with formation of the light-emitting device 190 just by adding a step of depositing the photoelectric conversion layer 113 in the manufacturing process of the light-emitting device 190. In addition, the light-emitting device 190 and the light-receiving device 110 can be formed over the same substrate. Accordingly, the light-receiving device 110 can be incorporated into the display device without a significant increase in the number of manufacturing steps.

In the display panel 50A, the light-receiving device 110 and the light-emitting device 190 can have a common structure except that the photoelectric conversion layer 113 of the light-receiving device 110 and the light-emitting layer 193 of the light-emitting device 190 are separately formed. Note that the structures of the light-receiving device 110 and the light-emitting device 190 are not limited thereto. The light-receiving device 110 and the light-emitting device 190 may include a separately formed layer other than the photoelectric conversion layer 113 and the light-emitting layer 193 (see display panels 50C, 50D, and 50E described later). The light-receiving device 110 and the light-emitting device 190 preferably include at least one layer used in common (common layer). Thus, the light-receiving device 110 can be incorporated into the display device without a significant increase in the number of manufacturing steps.

The display panel 50A includes the light-receiving device 110, the light-emitting device 190, a transistor 41, a transistor 42, and the like between a pair of substrates (a substrate 151 and a substrate 152).

In the light-receiving device 110, the common layer 112, the photoelectric conversion layer 113, and the common layer 114 that are positioned between the pixel electrode 111 and the common electrode 115 can each be referred to as an organic layer (a layer containing an organic compound). The pixel electrode 111 preferably has a function of reflecting infrared light. The common electrode 115 has a function of transmitting visible light and infrared light.

The light-receiving device 110 has a function of detecting light. Specifically, the light-receiving device 110 is a photoelectric conversion element that converts the incident light 74 into an electric signal.

A light-blocking layer 148 is provided on a surface of the substrate 152 on the substrate 151 side. The light-blocking layer 148 has opening potions in a position overlapping the light-receiving device 110 and in a position overlapping the light-emitting device 190.

Providing the light-blocking layer 148 can control the range where the light-receiving device 110 detects light.

A material that blocks light emitted from the light-emitting device 190 can be used for the light-blocking layer 148. The light-blocking layer 148 preferably absorbs visible light and infrared light. The light-blocking layer 148 can be formed using a metal material, a resin material containing pigment (e.g., carbon black) or dye, or the like, for example. The light-blocking layer 148 may have a stacked-layer structure of a red color filter, a green color filter, and a blue color filter.

In addition, a filter 149 that filters out light with wavelengths shorter than the wavelength of light (infrared light) emitted from the light-emitting device 190 is preferably provided in the opening portion of the light-blocking layer 148 that is provided in the position overlapping the light-receiving device 110. For example, a longpass filter that filters out light having shorter wavelengths than infrared light, a bandpass filter that filters out at least wavelengths in a visible light region, or the like can be used as the filter 149. A resin film or the like containing pigment or a semiconductor film such as an amorphous silicon thin film can be used as the filter that filters out visible light. When the filter 149 is provided, visible light can be inhibited from entering the light-receiving device 110, so that infrared light can be detected with less noise.

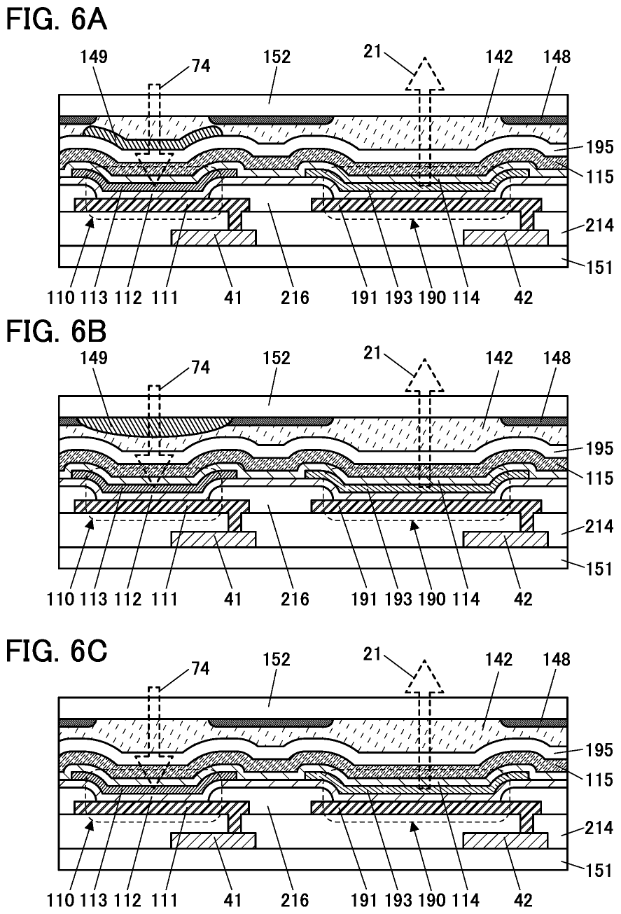

Note that the filter 149 may be provided to be stacked over the light-receiving device 110, as illustrated in FIG. 6A.

Alternatively, the filter 149 may have a lens shape as illustrated in FIG. 6B. The lens filter 149 is a convex lens having a convex surface on the substrate 151 side. Note that the filter 149 may be positioned so that the convex surface is on the substrate 152 side.

In the case where both the light-blocking layer 148 and the lens filter 149 are formed on the same surface of the substrate 152, their formation order is not limited. Although FIG. 6B illustrates an example in which the lens filter 149 is formed first, the light-blocking layer 148 may be formed first. In FIG. 6B, end portions of the lens filter 149 are covered with the light-blocking layer 148.

The structure illustrated in FIG. 6B is a structure in which the light 74 enters the light-receiving device 110 through the lens filter 149. When the filter 149 is a lens filter, the imaging range of the light-receiving device 110 can be narrowed to be inhibited from overlapping the imaging range of an adjacent light-receiving device 110. Thus, a clear image with little blurring can be captured. In addition, when the filter 149 is a lens filter, an opening of the light-blocking layer 148 over the light-receiving device 110 can be large. Thus, the amount of light entering the light-receiving device 110 can be increased, so that light detection sensitivity can be increased.

The lens filter 149 can be directly formed on the substrate 152 or on the light-receiving device 110. Alternatively, a separately manufactured microlens array or the like may be attached to the substrate 152.

Alternatively, a structure without the filter 149 may be employed as illustrated in FIG. 6C. The filter 149 can be omitted in the case where the light receiving device 110 has features such that it has no sensitivity to visible light or has sufficiently higher sensitivity to infrared light than that to visible light. In this case, a lens having a shape similar to that of the lens filter 149 illustrated in FIG. 6B may be provided to overlap the light-receiving device 110. The lens may be formed using a material that transmits visible light.

In the light-emitting device 190, the common layer 112, the light-emitting layer 193, and the common layer 114 that are positioned between the pixel electrode 191 and the common electrode 115 can each be referred to as an EL layer. The pixel electrode 191 preferably has a function of reflecting at least visible light.

The light-emitting device 190 has a function of emitting visible light. Specifically, the light-emitting device 190 is an electroluminescent device that emits light 21 to the substrate 152 side by application of voltage between the pixel electrode 191 and the common electrode 115.

The pixel electrode 111 is electrically connected to a source or a drain of the transistor 41 through an opening provided in the insulating layer 214. End portions of the pixel electrode 111 are covered with partitions 216.

The pixel electrode 191 is electrically connected to a source or a drain of the transistor 42 through an opening provided in the insulating layer 214. End portion of the pixel electrode 191 are covered with the partitions 216. The transistor 42 has a function of controlling driving of the light-emitting device 190.

The transistor 41 and the transistor 42 are on and in contact with the same layer (the substrate 151 in FIG. 5 and FIG. 6).

At least part of a circuit electrically connected to the light-receiving device 110 is preferably formed using the same material in the same steps as a circuit electrically connected to the light-emitting device 190. In that case, the thickness of the display device can be reduced compared with the case where the two circuits are separately formed, resulting in simplification of the manufacturing steps.

The light-receiving device 110 and the light-emitting device 190 are preferably covered with a protective layer 195. In FIG. 5 and FIG. 6 each illustrate an example in which the protective layer 195 is provided on and in contact with the common electrode 115. Providing the protective layer 195 can inhibit entry of impurities such as water into the light-receiving device 110 and the light-emitting device 190, so that the reliability of the light-receiving device 110 and the light-emitting device 190 can be increased. In addition, the protective layer 195 and the substrate 152 are attached to each other with an adhesive layer 142.

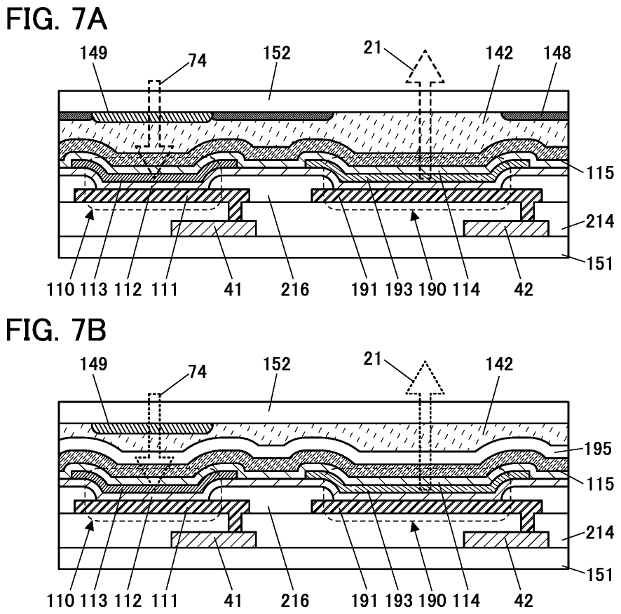

Alternatively, a structure in which no protective layer 195 is provided over the light-receiving device 110 and over the light-emitting device 190 may be employed, as illustrated in FIG. 7A. In this case, the common electrode 115 and the substrate 152 are attached to each other with the adhesive layer 142.

Alternatively, a structure without the light-blocking layer 148 may be employed, as illustrated in FIG. 7B. Thus, the amount of light emitted from the light-emitting device 190 to the outside and the amount of light received by the light-receiving device 110 can be increased, so that detection sensitivity can be increased.

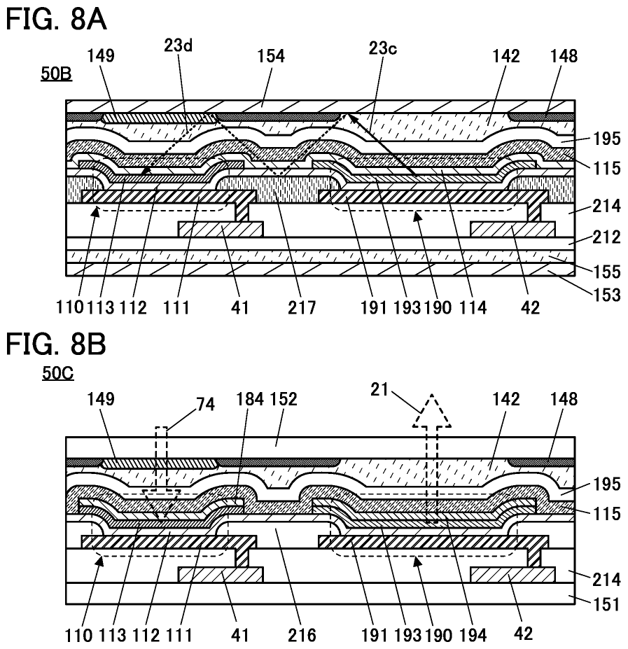

In addition, the display panel according to one embodiment of the present invention may have a structure of a display panel 50B illustrated in FIG. 8A. The display panel 50B differs from the display panel 50A in that the substrate 151, the substrate 152, and the partition 216 are not included and a substrate 153, a substrate 154, an adhesive layer 155, an insulating layer 212, and a partition 217 are included.

The substrate 153 and the insulating layer 212 are attached to each other with the adhesive layer 155. The substrate 154 and the protective layer 195 are attached to each other with the adhesive layer 142.

The display panel 50B has a structure manufactured in such a manner that the insulating layer 212, the transistor 41, the transistor 42, the light-receiving device 110, the light-emitting device 190, and the like that are formed over a formation substrate are transferred onto the substrate 153. The substrate 153 and the substrate 154 are preferably flexible.

Accordingly, flexibility can be imparted to the display panel 50B. For example, a resin is preferably used for the substrate 153 and the substrate 154.

For the substrate 153 and the substrate 154, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for one or both of the substrate 153 and the substrate 154.

As the substrate included in the display device of this embodiment, a film having high optical isotropy may be used. Examples of the film having high optical isotropy include a triacetyl cellulose (TAC, also referred to as cellulose triacetate) film, a cycloolefin polymer (COP) film, a cycloolefin copolymer (COC) film, and an acrylic film.

The partition 217 is preferably capable of absorbing light emitted from the light-emitting device 190. The partition 217 can be formed using, for example, a resin material or the like containing pigment or dye.

Part of light 23c emitted from the light-emitting device 190 is reflected by the substrate 154 and the partition 217. Reflected light 23d sometimes enters the light-receiving device 110. In other cases, the light 23c passes through the partition 217 and is reflected by a transistor, a wiring, or the like, and thus reflected light sometimes enters the light-receiving device 110. When the partition 217 absorbs the light 23c, the reflected light 23d can be inhibited from entering the light-receiving device 110. Consequently, noise can be reduced and the accuracy of light detection of the light-receiving device 110 can be increased.

The partition 217 preferably absorbs at least light with a wavelength that can be detected by the light-receiving device 110. For example, in the case where the light-receiving device 110 detects visible light emitted from the light-emitting device 190, the partition 217 is preferably capable of absorbing visible light.

Although the light-emitting device and the light-receiving device include two common layers in the above examples, one embodiment of the present invention is not limited thereto. Examples in which common layers have different structures are described below.

FIG. 8B illustrates a schematic cross-sectional view of the display panel 50C. The display panel 50C differs from the display panel 50A in that the common layer 114 is not included and a buffer layer 184 and a buffer layer 194 are included. The buffer layer 184 and the buffer layer 194 may each have either a single-layer structure or a stacked-layer structure.

In the display panel 50C, the light-receiving device 110 includes the pixel electrode 111, the common layer 112, the photoelectric conversion layer 113, the buffer layer 184, and the common electrode 115. In addition, in the display panel 50C, the light-emitting device 190 includes the pixel electrode 191, the common layer 112, the light-emitting layer 193, the buffer layer 194, and the common electrode 115.

In the display panel 50C, an example is shown in which the buffer layer 184 between the common electrode 115 and the photoelectric conversion layer 113 and the buffer layer 194 between the common electrode 115 and the light-emitting layer 193 are separately formed. As each of the buffer layer 184 and the buffer layer 194, one or both of an electron-injection layer and an electron-transport layer can be formed, for example.

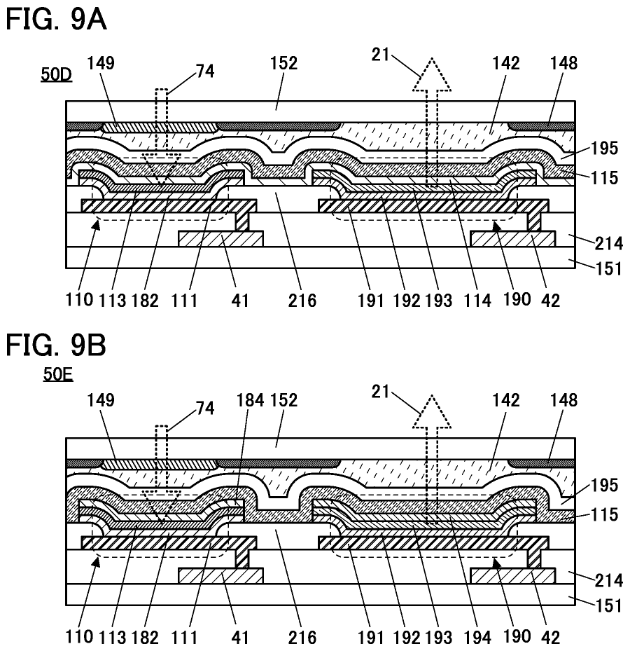

FIG. 9A illustrates a schematic cross-sectional view of the display panel 50D. The display panel 50D differs from the display panel 50A in that the common layer 112 is not included and a buffer layer 182 and a buffer layer 192 are included. The buffer layer 182 and the buffer layer 192 may each have either a single-layer structure or a stacked-layer structure.

In the display panel 50D, the light-receiving device 110 includes the pixel electrode 111, the buffer layer 182, the photoelectric conversion layer 113, the common layer 114, and the common electrode 115. In addition, in the display panel 50D, the light-emitting device 190 includes the pixel electrode 191, the buffer layer 192, the light-emitting layer 193, the common layer 114, and the common electrode 115.

In the display panel 50D, an example is shown in which the buffer layer 182 between the pixel electrode 111 and the photoelectric conversion layer 113 and the buffer layer 192 between the pixel electrode 191 and the light-emitting layer 193 are separately formed. As each of the buffer layer 182 and the buffer layer 192, one or both of a hole-injection layer and a hole-transport layer can be formed, for example.

FIG. 9B illustrates a schematic cross-sectional view of the display panel 50E. The display panel 50E differs from the display panel 50A in that the common layer 112 and the common layer 114 are not included and the buffer layer 182, the buffer layer 184, the buffer layer 192, and the buffer layer 194 are included.

In the display panel 50E, the light-receiving device 110 includes the pixel electrode 111, the buffer layer 182, the photoelectric conversion layer 113, the buffer layer 184, and the common electrode 115. In addition, in the display panel 50E, the light-emitting device 190 includes the pixel electrode 191, the buffer layer 192, the light-emitting layer 193, the buffer layer 194, and the common electrode 115.

Other layers as well as the photoelectric conversion layer 113 and the light-emitting layer 193 can be separately formed in the manufacturing process of the light-receiving device 110 and the light-emitting device 190.

An example is shown in which the light-receiving device 110 and the light-emitting device 190 do not have a common layer between the pair of electrodes (the pixel electrode 111 or the pixel electrode 191 and the common electrode 115) in the display panel 50E. In the manufacturing process of the light-receiving device 110 and the light-emitting device 190 included in the display panel 50E, first, the pixel electrode 111 and the pixel electrode 191 are formed over the insulating layer 214 using the same material in the same step. Then, the buffer layer 182, the photoelectric conversion layer 113, and the buffer layer 184 are formed over the pixel electrode 111; the buffer layer 192, the light-emitting layer 193, and the buffer layer 194 are formed over the pixel electrode 191; and the common electrode 115 is formed to cover the buffer layer 184, the buffer layer 194, and the like.

Note that the manufacturing order of the stacked-layer structure of the buffer layer 182, the photoelectric conversion layer 113, and the buffer layer 184 and the stacked-layer structure of the buffer layer 192, the light-emitting layer 193, and the buffer layer 194 is not particularly limited. For example, after the buffer layer 182, the photoelectric conversion layer 113, and the buffer layer 184 are deposited, the buffer layer 192, the light-emitting layer 193, and the buffer layer 194 may be manufactured. In contrast, the buffer layer 192, the light-emitting layer 193, and the buffer layer 194 may be manufactured before the buffer layer 182, the photoelectric conversion layer 113, and the buffer layer 184 are deposited. Alternatively, alternate deposition of the buffer layer 182, the buffer layer 192, the photoelectric conversion layer 113, and the light-emitting layer 193, and the like in this order is also possible.

A more specific structure example of the display panel according to one embodiment of the present invention will be described below.

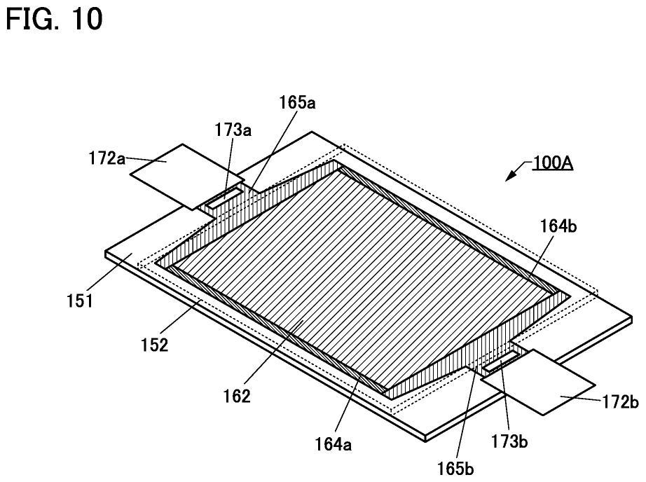

FIG. 10 illustrates a perspective view of a display panel 100A. The display panel 100A has a structure in which the substrate 151 and the substrate 152 are attached to each other. In FIG. 10, the substrate 152 is denoted by a dashed line.

The display panel 100A includes a display portion 162, a circuit 164a, a circuit 164b, a wiring 165a, a wiring 165b, and the like. FIG. 10 also illustrates an example in which an IC (integrated circuit) 173a, an FPC 172a, an IC 173b, and an FPC 172b are mounted on the display panel 100A. Therefore, the structure illustrated in FIG. 10 can be regarded as a display module including the display panel 100A, the ICs, and the FPCs.

A gate driver for performing display can be used as the circuit 164a. A row driver for performing imaging (light detection) can be used as the circuit 164b.

The wiring 165a has a function of supplying a signal and power to the subpixels 11 and 12 and the circuit 164a. The signal and the power are input to the wiring 165a from the outside through the FPC 172a or input to the wiring 165a from the IC 173a.

In addition, the wiring 165b has a function of supplying a signal and power to the subpixel 12 and the circuit 164b. The signal and the power are input to the wiring 165b from the outside through the FPC 172b or input to the wiring 165b from the IC 173b.

Although FIG. 10 illustrates an example in which the ICs 173a and 173b are provided on the substrate 151 by a COG (Chip On Glass) method, a TCP (Tape Carrier Package) method, a COF (Chip On Film) method, or the like may be used. An IC having a function of a source driver connected to the subpixels 11 and 12 can be used as the IC 173a, for example. Furthermore, an IC having functions of a column driver connected to the subpixel 12 and a signal processing circuit such as an A/D converter can be used as the IC 173b, for example.

Note that the driver circuits as well as the transistor included in the pixel circuit and the like may be provided over the substrate 151.

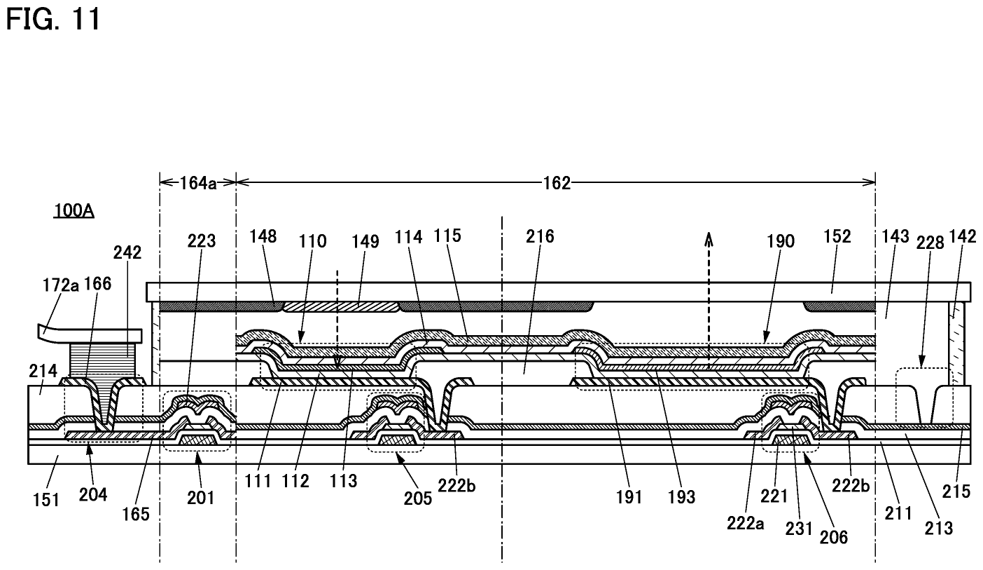

FIG. 11 illustrates an example of cross sections of part of a region including the FPC 172a, part of a region including the circuit 164a, part of a region including the display portion 162, and part of a region including an end portion in the display panel 100A illustrated in FIG. 10.

The display panel 100A illustrated in FIG. 11 includes a transistor 201, a transistor 205, a transistor 206, the light-emitting device 190, the light-receiving device 110, and the like between the substrate 151 and the substrate 152.

The substrate 152 and the insulating layer 214 are bonded to each other with the adhesive layer 142. A solid sealing structure, a hollow sealing structure, or the like can be employed to seal the light-emitting device 190 and the light-receiving device 110. A hollow sealing structure is employed in which a space 143 surrounded by the substrate 152, the adhesive layer 142, and the insulating layer 214 is filled with an inert gas (nitrogen, argon, or the like).

The adhesive layer 142 may be provided to overlap the light-emitting device 190. In addition, a region surrounded by the substrate 152, the adhesive layer 142, and the insulating layer 214 may be filled with a resin different from that of the adhesive layer 142.

The light-emitting device 190 has a stacked-layer structure in which the pixel electrode 191, the common layer 112, the light-emitting layer 193, the common layer 114, and the common electrode 115 are stacked in this order from the insulating layer 214 side. The pixel electrode 191 is connected to a conductive layer 222b included in the transistor 206 through an opening provided in the insulating layer 214. The transistor 206 has a function of controlling driving of the light-emitting device 190. End portions of the pixel electrodes 191 are covered with the partition 216.

The light-receiving device 110 has a stacked-layer structure in which the pixel electrode 111, the common layer 112, the photoelectric conversion layer 113, the common layer 114, and the common electrode 115 are stacked in that order from the insulating layer 214 side.

The pixel electrode 111 is electrically connected to the conductive layer 222b included in the transistor 205 through an opening provided in the insulating layer 214. The end portion of the pixel electrode 111 is covered with the partition 216.

Light from the light-emitting device 190 is emitted toward the substrate 152 side. In addition, light enters the light-receiving device 110 through the substrate 152 and the space 143. For the substrate 152, a material having a high transmitting property with respect to visible light and infrared light is preferably used.

The pixel electrode 111 and the pixel electrode 191 can be manufactured using the same material in the same step. The common layer 112, the common layer 114, and the common electrode 115 are used in both the light-receiving device 110 and the light-emitting device 190. The light-receiving device 110 and the light-emitting device 190 can have common structures except that the structures of the photoelectric conversion layer 113 and the light-emitting layer 193 are different. Thus, the light-receiving device 110 can be incorporated into the display panel 100A without a significant increase in the number of manufacturing steps.

A light-blocking layer 148 is provided on a surface of the substrate 152 on the substrate 151 side. The light-blocking layer 148 has openings in a position overlapping the light-receiving device 110 and in a position overlapping the light-emitting device 190. In addition, the filter 149 that filters out visible light is provided in a position overlapping the light-receiving device 110. Note that a structure without the filter 149 can be employed.

The transistor 201, the transistor 205, and the transistor 206 are all formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may be either a single layer or two or more layers.

A material into which impurities such as water and hydrogen are less likely to diffuse is preferably used for at least one of the insulating layers that cover the transistors. This allows the insulating layer to serve as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. A stack including two or more of the above insulating films may also be used.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property against impurities than an inorganic insulating film. Therefore, the organic insulating film preferably has an opening in the vicinity of an end portion of the display panel 100A. This can inhibit diffusion of impurities from the end portion of the display panel 100A through the organic insulating film. Alternatively, in order to prevent the organic insulating film from being exposed at the end portion of the display panel 100A, the organic insulating film may be formed so that its end portion is positioned on the inner side compared to the end portion of the display panel 100A.

In a region 228 illustrated in FIG. 11, an opening is formed in the insulating layer 214. This can inhibit diffusion of impurities into the display portion 162 from the outside through the insulating layer 214 even when an organic insulating film is used as the insulating layer 214. Thus, the reliability of the display panel 100A can be increased.

The transistor 201, the transistor 205, and the transistor 206 each include a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are illustrated with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structures of the transistors included in the display device of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

A structure in which the semiconductor layer where a channel is formed is sandwiched between the two gates is used for the transistor 201, the transistor 205, and the transistor 206. The two gates may be connected to each other and supplied with the same signal to drive the transistor. Alternatively, one of the two gates may be supplied with a potential for controlling the threshold voltage of the transistor and the other may be supplied with a potential for driving.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

A semiconductor layer of a transistor preferably contains a metal oxide (also referred to as an oxide semiconductor). Alternatively, the semiconductor layer of the transistor may contain silicon. Examples of silicon include amorphous silicon and crystalline silicon (low-temperature polysilicon, single crystal silicon, and the like).

The semiconductor layer preferably contains indium, M (M is one kind or a plurality kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one kind or a plurality kinds selected from aluminum, gallium, yttrium, and tin.

It is particularly preferable to use an oxide containing indium (In), gallium (Ga), and zinc (Zn) (also referred to as IGZO) for the semiconductor layer.

In the case where an In—M—Zn oxide is deposited by a sputtering method, the atomic proportion of In is preferably higher than or equal to the atomic proportion of M in a sputtering target. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, and In:M:Zn =5:2:5.

A target including a polycrystalline oxide is preferably used as the sputtering target because the semiconductor layer having crystallinity is easily formed. Note that the atomic ratio in the deposited semiconductor layer varies from the atomic ratio of metal elements contained in the sputtering target in a range of ±40%. For example, in the case where the composition of a sputtering target used for the semiconductor layer is In:Ga:Zn=4:2:4.1 [atomic ratio], the composition of the deposited semiconductor layer is sometimes in the neighborhood of In:Ga:Zn=4:2:3 [atomic ratio].

Note that when the atomic ratio is described as In:Ga:Zn=4:2:3 or as being in the neighborhood thereof, the case is included where the atomic proportion of Ga is higher than or equal to 1 and lower than or equal to 3 and the atomic proportion of Zn is higher than or equal to 2 and lower than or equal to 4 with the atomic proportion of In being 4. In addition, when the atomic ratio is described as In:Ga:Zn=5:1:6 or as being in the neighborhood thereof, the case is included where the atomic proportion of Ga is higher than 0.1 and lower than or equal to 2 and the atomic proportion of Zn is higher than or equal to 5 and lower than or equal to 7 with the atomic proportion of In being 5. Furthermore, when the atomic ratio is described as In:Ga:Zn=1:1:1 or as being in the neighborhood thereof, the case is included where the atomic proportion of Ga is higher than 0.1 and lower than or equal to 2 and the atomic proportion of Zn is higher than 0.1 and lower than or equal to 2 with the atomic proportion of In being 1.

The transistors included in the circuit 164a and the transistors included in the display portion 162 may have either the same structure or different structures. A plurality of transistors included in the circuit 164a may have either the same structure or two or more kinds of structures. Similarly, a plurality of transistors included in the display portion 162 may have either the same structure or two or more kinds of structures.

A connection portion 204 is provided in a region that is over the substrate 151 and does not overlap the substrate 152. In the connection portion 204, the wiring 165 is electrically connected to the FPC 172a through a conductive layer 166 and a connection layer 242. On a top surface of the connection portion 204, the conductive layer 166 obtained by processing the same conductive film as the pixel electrode 191 is exposed. Thus, the connection portion 204 and the FPC 172a can be electrically connected to each other through the connection layer 242.

A variety of optical members can be arranged on an outer side of the substrate 152. Examples of the optical members include a polarizing plate, a retardation plate, a light diffusion layer (a diffusion film or the like), an anti-reflective layer, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outer side of the substrate 152.

Glass, quartz, ceramic, sapphire, a resin, or the like can be used for the substrate 151 and the substrate 152.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. Alternatively, an adhesive sheet or the like may be used.

As the connection layer 242, an anisotropic conductive film (ACF), an anisotropic conductive paste (ACP), or the like can be used.

The light-emitting device 190 may be of a top emission type, a bottom emission type, a dual emission type, or the like. Although the light-emitting device 190 is preferably of a top emission type in one embodiment of the present invention, another structure can be employed when a light-emitting surface of the light-emitting device 190 and a light incident surface of the light-receiving device 110 face in the same direction.

The light-emitting device 190 includes at least the light-emitting layer 193. The light-emitting device 190 may further include, as a layer other than the light-emitting layer 193, a layer containing a substance with a high hole-injection property, a substance with a high hole-transport property, a hole-blocking material, a substance with a high electron-transport property, a substance with a high electron-injection property, a substance with a bipolar property (a substance with a high electron- and hole-transport property), or the like. For example, the common layer 112 preferably includes one or both of a hole-injection layer and a hole-transport layer. For example, the common layer 114 preferably includes one or both of an electron-transport layer and an electron-injection layer.

Either a low molecular compound or a high molecular compound can be used for the common layer 112, the light-emitting layer 193, and the common layer 114, and an inorganic compound may be contained. The layers included in the common layer 112, the light-emitting layer 193, and the common layer 114 can be formed by a method such as an evaporation method (including a vacuum evaporation method), a transfer method, a printing method, an inkjet method, or a coating method.

The light-emitting layer 193 may contain an inorganic compound such as quantum dots as a light-emitting material.

The photoelectric conversion layer 113 of the light-receiving device 110 contains a semiconductor. As the semiconductor, an inorganic semiconductor such as silicon or an organic semiconductor containing an organic compound can be used. This embodiment shows an example in which an organic semiconductor is used as the semiconductor included in the photoelectric conversion layer 113. The use of an organic semiconductor is preferable because the light-emitting layer 193 of the light-emitting device 190 and the photoelectric conversion layer 113 of the light-receiving device 110 can be formed by the same method (e.g., a vacuum evaporation method) and thus a manufacturing apparatus can be used in common.

Examples of an n-type semiconductor material contained in the photoelectric conversion layer 113 include electron-accepting organic semiconductor materials such as fullerene (e.g., C₆₀ and C₇₀) and derivatives thereof. In addition, examples of a p-type semiconductor material contained in the photoelectric conversion layer 113 include electron-donating organic semiconductor materials such as copper(II) phthalocyanine (CuPc), tetraphenyldibenzoperiflanthene (DBP), and zinc phthalocyanine (ZnPc).

For example, the photoelectric conversion layer 113 can be formed by co-evaporation of an n-type semiconductor and a p-type semiconductor.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A film containing these materials can be used as a single-layer structure or a stacked-layer structure.

In addition, as a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is made thin enough to have a light-transmitting property. Furthermore, a stacked-layer film of the above materials can be used for a conductive layer. For example, a stacked-layer film of indium tin oxide and an alloy of silver and magnesium, or the like is preferably used for increased conductivity. They can also be used for conductive layers such as a variety of wirings and electrodes that constitute a display device, and conductive layers (conductive layers functioning as a pixel electrode or a common electrode) included in a display element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

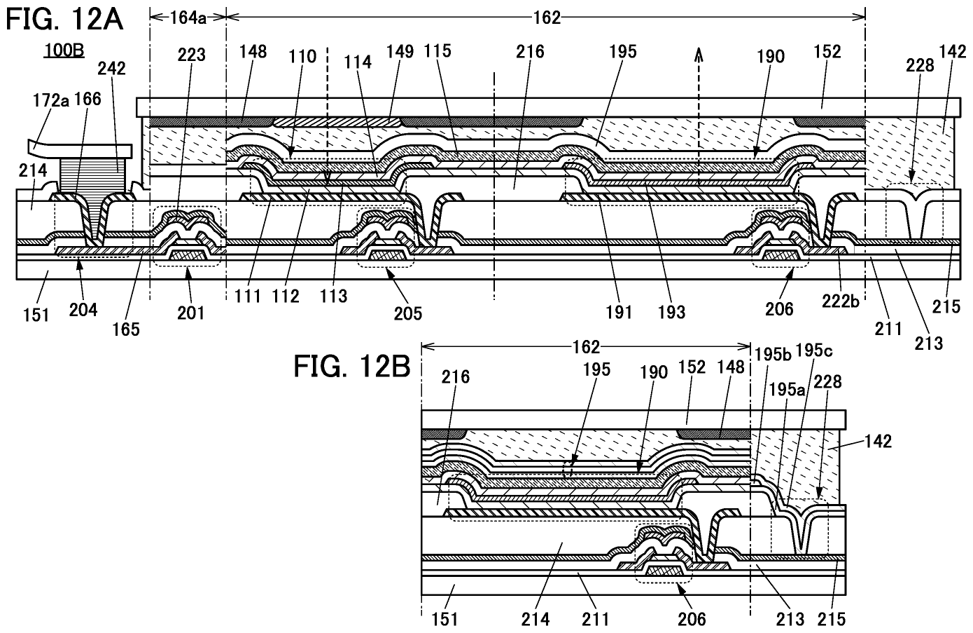

FIG. 12A illustrates a cross-sectional view of a display panel 100B. The display panel 100B differs from the display panel 100A mainly in that the protective layer 195 is included.

Providing the protective layer 195 that covers the light-receiving device 110 and the light-emitting device 190 can inhibit diffusion of impurities such as water into the light-receiving device 110 and the light-emitting device 190, so that the reliability of the light-receiving device 110 and the light-emitting device 190 can be increased.

In the region 228 in the vicinity of an end portion of the display panel 100B, the insulating layer 215 and the protective layer 195 are preferably in contact with each other through an opening in the insulating layer 214. In particular, the inorganic insulating film included in the insulating layer 215 and the inorganic insulating film included in the protective layer 195 are preferably in contact with each other. Thus, diffusion of impurities from the outside into the display portion 162 through the organic insulating film can be inhibited. Consequently, the reliability of the display panel 100B can be increased.

FIG. 12B illustrates an example in which the protective layer 195 has a three-layer structure. The protective layer 195 includes an inorganic insulating layer 195a over the common electrode 115, an organic insulating layer 195b over the inorganic insulating layer 195a, and an inorganic insulating layer 195c over the organic insulating layer 195b.

An end portion of the inorganic insulating layer 195a and an end portion of the inorganic insulating layer 195c extend beyond an end portion of the organic insulating layer 195b and are in contact with each other. In addition, the inorganic insulating layer 195a is in contact with the insulating layer 215 (inorganic insulating layer) through the opening in the insulating layer 214 (organic insulating layer). Accordingly, the light-receiving device 110 and the light-emitting device 190 can be surrounded by the insulating layer 215 and the protective layer 195, so that the reliability of the light-receiving device 110 and the light-emitting device 190 can be increased.

As described above, the protective layer 195 may have a stacked-layer structure of an organic insulating film and an inorganic insulating film. In that case, an end portion of the inorganic insulating film preferably extends beyond an end portion of the organic insulating film.

In addition, in the display panel 100B, the protective layer 195 and the substrate 152 are attached to each other with the adhesive layer 142. The adhesive layer 142 is provided to overlap each of the light-receiving device 110 and the light-emitting device 190, and the display panel 100B employs a solid sealing structure.

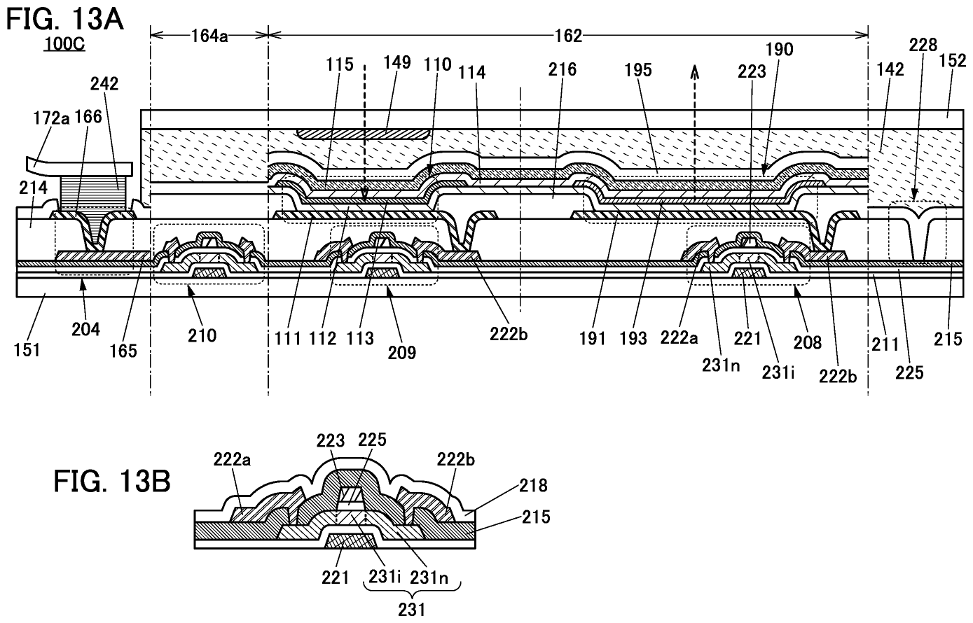

FIG. 13A illustrates a cross-sectional view of a display panel 100C. The display panel 100C differs from the display panel 100B mainly in the structures of transistors and in not including the light-blocking layer 148.

The display panel 100C includes a transistor 208, a transistor 209, and a transistor 210 over the substrate 151.

The transistor 208, the transistor 209, and the transistor 210 each include the conductive layer 221 functioning as a gate, the insulating layer 211 functioning as a gate insulating layer, a semiconductor layer including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

The pixel electrode 191 of the light-emitting device 190 is electrically connected to the other of the pair of low-resistance regions 231n of the transistor 208 through the conductive layer 222b.

The pixel electrode 111 of the light-receiving device 110 is electrically connected to the other of the pair of low-resistance regions 231n of the transistor 209 through the conductive layer 222b.

FIG. 13A illustrates an example in which the insulating layer 225 covers a top surface and a side surface of the semiconductor layer. FIG. 13B illustrates an example in which the insulating layer 225 overlaps the channel formation region 231i of the semiconductor layer 231 and does not overlap the low-resistance regions 231n. The structure illustrated in FIG. 13B can be manufactured by processing the insulating layer 225 using the conductive layer 223 as a mask, for example. In FIG. 13B, the insulating layer 215 is provided to cover the insulating layer 225 and the conductive layer 223, and the conductive layer 222a and the conductive layer 222b are connected to the low-resistance regions 231n through openings in the insulating layer 215. Furthermore, an insulating layer 218 covering the transistor may be provided.

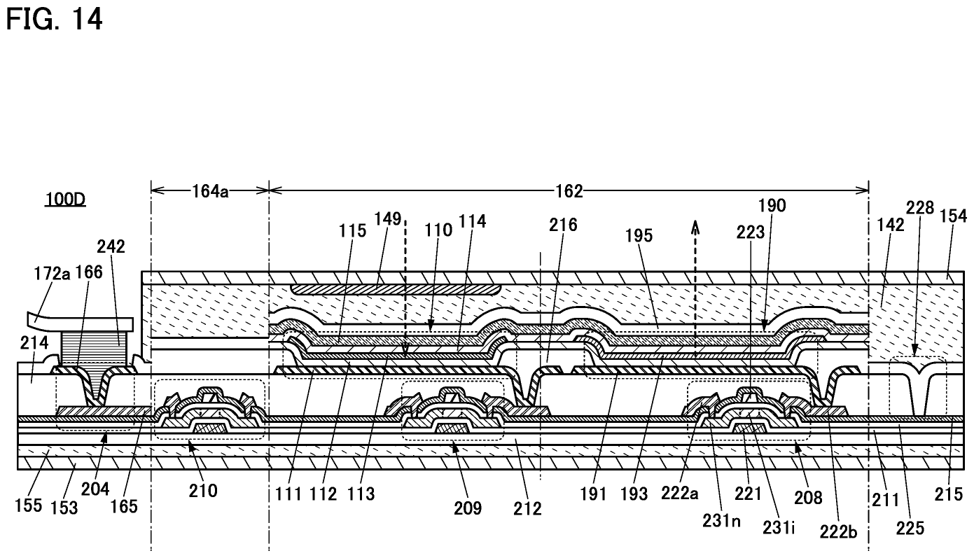

FIG. 14 illustrates a cross-sectional view of a display panel 100D. The display panel 100D differs from the display panel 100C mainly in the structures of the substrates.

The display panel 100D does not include the substrate 151 and the substrate 152 and includes the substrate 153, the substrate 154, the adhesive layer 155, and the insulating layer 212.

The substrate 153 and the insulating layer 212 are attached to each other with the adhesive layer 155. The substrate 154 and the protective layer 195 are attached to each other with the adhesive layer 142.

The display panel 100D is manufactured in such a manner that the insulating layer 212, the transistor 208, the transistor 209, the light-receiving device 110, the light-emitting device 190, and the like that are formed over a formation substrate are transferred onto the substrate 153.

The substrate 153 and the substrate 154 are preferably flexible. Accordingly, flexibility can be imparted to the display panel 100D.

An inorganic insulating film that can be used for the insulating layer 211, the insulating layer 213, and the insulating layer 215 can be used for the insulating layer 212. Alternatively, a stacked-layer film of an organic insulating film and an inorganic insulating film may be used for the insulating layer 212. At this time, a film on the transistor 209 side is preferably an inorganic insulating film.

The above is the description of the structure examples of the display device.

The display device of this embodiment includes a light-receiving device and a light-emitting device in a display portion, and the display portion has both a function of displaying an image and a function of detecting light. Thus, the size and weight of an electronic device can be reduced as compared to the case where a sensor is provided outside a display portion or outside a display device. Moreover, an electronic device having more functions can be achieved by a combination of the display device of this embodiment and a sensor provided outside the display portion or outside the display device.

In the light-receiving device, at least one layer other than the photoelectric conversion layer can have a structure in common with the layer in the light-emitting device (the EL element). In addition, in the light-receiving device, all the layers other than the photoelectric conversion layer may have structures in common with the layers in the light-emitting device (EL element). With only addition of the step of depositing the photoelectric conversion layer to the manufacturing process of the light-emitting device, the light-emitting device and the light-receiving device can be formed over the same substrate, for example. Furthermore, in the light-receiving device and the light-emitting device, the pixel electrodes and the common electrode can be formed using the same material in the same step. Moreover, when a circuit electrically connected to the light-receiving device and a circuit electrically connected to the light-emitting device are formed using the same material in the same step, the manufacturing process of the display device can be simplified. In such a manner, a display device that incorporates a light-receiving device and is highly convenient can be manufactured without complicated steps.

A metal oxide that can be applied to the semiconductor layer of the transistor will be described below.

Note that in this specification and the like, a metal oxide containing nitrogen is also collectively referred to as a metal oxide in some cases. Alternatively, a metal oxide containing nitrogen may be referred to as a metal oxynitride. For example, a metal oxide containing nitrogen, such as zinc oxynitride (ZnON), may be used for the semiconductor layer.

Note that the terms “CAAC (c-axis aligned crystal)” and “CAC (Cloud-Aligned Composite)” might appear in this specification and the like. CAAC refers to an example of a crystal structure, and CAC refers to an example of a function or a material composition.

For example, a CAC (Cloud-Aligned Composite)-OS (Oxide Semiconductor) can be used for the semiconductor layer.

A CAC-OS or a CAC-metal oxide has a conducting function in part of the material and has an insulating function in another part of the material; as a whole, the CAC-OS or the CAC-metal oxide has a function of a semiconductor. Note that in the case where the CAC-OS or the CAC-metal oxide is used for a semiconductor layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

In addition, the CAC-OS or the CAC-metal oxide includes conductive regions and insulating regions. The conductive regions have the above conducting function, and the insulating regions have the above insulating function. Furthermore, in some cases, the conductive regions and the insulating regions in the material are separated at the nanoparticle level. Furthermore, in some cases, the conductive regions and the insulating regions are unevenly distributed in the material. Moreover, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow through the component having a narrow gap. Moreover, the component having a narrow gap complements the component having a wide gap, and carriers also flow through the component having a wide gap in conjunction with the component having a narrow gap. Therefore, in the case where the CAC-OS or the CAC-metal oxide is used for the channel formation region of the transistor, high current drive capability in an on state of the transistor, that is, high on-state current and high field-effect mobility can be obtained.

In other words, the CAC-OS or the CAC-metal oxide can also be referred to as a matrix composite or a metal matrix composite.

Oxide semiconductors (metal oxides) are classified into a single crystal oxide semiconductor and a non-single crystal oxide semiconductor. Examples of a non-single crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of lattice arrangement changes between a region with regular lattice arrangement and another region with regular lattice arrangement in a region where the plurality of nanocrystals are connected.

The nanocrystal is basically a hexagon but is not always a regular hexagon and is a non-regular hexagon in some cases. Furthermore, pentagonal lattice arrangement, heptagonal lattice arrangement, and the like are included in the distortion in some cases. Note that it is difficult to observe a clear crystal grain boundary (also referred to as grain boundary) even in the vicinity of distortion in the CAAC-OS. That is, formation of a crystal grain boundary is found to be inhibited by the distortion of lattice arrangement. This is because the CAAC-OS can tolerate distortion owing to the low density of oxygen atom arrangement in the a-b plane direction, a change in interatomic bond distance by replacement of a metal element, and the like.

Furthermore, the CAAC-OS tends to have a layered crystal structure (also referred to as a layered structure) in which a layer containing indium and oxygen (hereinafter referred to as an

In layer) and a layer containing the element M, zinc, and oxygen (hereinafter referred to as an (M,Zn) layer) are stacked. Note that indium and the element M can be replaced with each other, and when the element M in the (M,Zn) layer is replaced with indium, the layer can also be referred to as an (In,M,Zn) layer. Moreover, when indium in the In layer is replaced with the element M, the layer can also be referred to as an (In,M) layer.

The CAAC-OS is a metal oxide with high crystallinity. Meanwhile, a clear crystal grain boundary is difficult to observe in the CAAC-OS; thus, it can be said that a reduction in electron mobility due to the crystal grain boundary is less likely to occur. In addition, the mixing of impurities, formation of defects, or the like might decrease the crystallinity of a metal oxide; thus, it can be said that the CAAC-OS is a metal oxide that has small amounts of impurities and defects (oxygen vacancies (also referred to as V_{O}) or the like). Thus, a metal oxide including a CAAC-OS is physically stable. Therefore, the metal oxide including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS and an amorphous oxide semiconductor depending on the analysis method.

Note that indium-gallium-zinc oxide (hereinafter IGZO), which is a kind of metal oxide containing indium, gallium, and zinc, has a stable structure in some cases by being formed of the above nanocrystals. In particular, crystals of IGZO tend not to grow in the air and thus a stable structure is obtained in some cases when IGZO is formed of smaller crystals (e.g., the above nanocrystals) rather than larger crystals (here, crystals with a size of several millimeters or several centimeters).

The a-like OS is a metal oxide that has a structure between those of the nc-OS and the amorphous oxide semiconductor. The a-like OS includes a void or a low-density region. That is, the a-like OS has lower crystallinity than the nc-OS and the CAAC-OS.

An oxide semiconductor (metal oxide) has various structures with different properties.

Two or more kinds of the amorphous oxide semiconductor, the polycrystalline oxide semiconductor, the a-like OS, the nc-OS, and the CAAC-OS may be included in an oxide semiconductor of one embodiment of the present invention.

A metal oxide film that functions as a semiconductor layer can be deposited by a sputtering method using either one or both an inert gas and an oxygen gas. Note that there is no particular limitation on the flow rate ratio of oxygen (partial pressure of oxygen) at the time of depositing the metal oxide film. However, to obtain a transistor having high field-effect mobility, the flow rate ratio of oxygen (partial pressure of oxygen) at the time of depositing the metal oxide film is preferably higher than or equal to 0% and lower than or equal to 30%, further preferably higher than or equal to 5% and lower than or equal to 30%, still further preferably higher than or equal to 7% and lower than or equal to 15%.

The energy gap of the metal oxide is preferably greater than or equal to 2 eV, further preferably greater than or equal to 2.5 eV, still further preferably greater than or equal to 3 eV.

With the use of a metal oxide having such a wide energy gap, the off-state current of the transistor can be reduced.

A transistor using the metal oxide can exhibit characteristics with an extremely low off-state current of several yoctoamperes per micrometer (a current value per micrometer of channel width). In addition, the transistor using the metal oxide has features such that impact ionization, an avalanche breakdown, a short-channel effect, or the like does not occur, which are different from those of a transistor using Si. Thus, a highly reliable circuit can be formed. Moreover, variations in electrical characteristics due to crystallinity unevenness, which are caused in transistors using Si, are less likely to occur in the transistors using the metal oxide.

The substrate temperature during the deposition of the metal oxide film is preferably lower than or equal to 350° C., further preferably higher than or equal to room temperature and lower than or equal to 200° C., still further preferably higher than or equal to room temperature and lower than or equal to 130° C. The substrate temperature during the deposition of the metal oxide film is preferably room temperature because productivity can be increased.

The metal oxide film can be formed by a sputtering method, a PLD method, a PECVD method, a thermal CVD method, an MOCVD method, an ALD method, a vacuum evaporation method, or the like.

The above is the description of the metal oxide.

At least part of this embodiment can be implemented in combination with the other embodiment described in this specification as appropriate.

### (Embodiment 2)

In this embodiment, pixel circuits included in a display device according to one embodiment of the present invention will be described.

A pixel of the display device according to one embodiment of the present invention includes the subpixels 11 and 12. A pixel circuit PIX1 of the subpixel 11 includes a light-emitting device that emits visible light. A pixel circuit PIX2 of the subpixel 12 includes a light-receiving device.

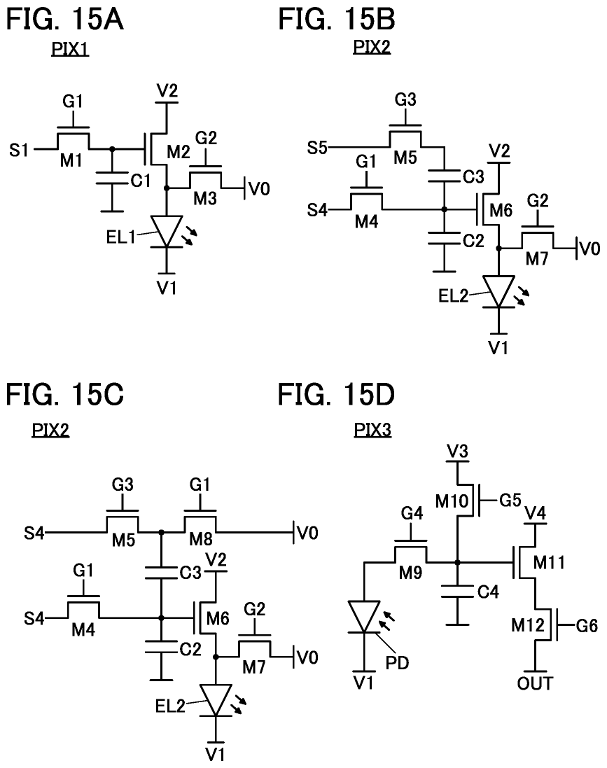

FIG. 15A illustrates an example of the pixel circuit PIX1 of the subpixel 11. The pixel circuit PIX1 includes a light-emitting device EL1, a transistor M1, a transistor M2, a transistor M3, and a capacitor C1. Here, an example in which a light-emitting diode is used as the light-emitting device EL1 is illustrated. An organic EL element that emits visible light is preferably used as the light-emitting device EL1.

A gate of the transistor M1 is electrically connected to a wiring G1, one of a source and a drain of the transistor M1 is electrically connected to a wiring S1, and the other of the source and the drain of the transistor M1 is electrically connected to one electrode of the capacitor C1 and a gate of the transistor M2. One of a source and a drain of the transistor M2 is electrically connected to a wiring V2, and the other of the source and the drain of the transistor M2 is electrically connected to an anode of the light-emitting device EL1 and one of a source and a drain of the transistor M3. A gate of the transistor M3 is electrically connected to a wiring G2, and the other of the source and the drain of the transistor M3 is electrically connected to a wiring V0. A cathode of the light-emitting device EL1 is electrically connected to a wiring V1.

A constant potential is supplied to each of the wiring V1 and the wiring V2. Light emission can be performed when the anode side of the light-emitting device EL1 is set to a high potential and the cathode side of the light-emitting device EL1 is set to a low potential. The transistor M1 is controlled by a signal supplied to the wiring G1 and functions as a selection transistor for controlling the selection state of the pixel circuit PIX1. In addition, the transistor M2 functions as a driving transistor that controls current flowing through the light-emitting device EL1 in accordance with a potential supplied to the gate.

When the transistor M1 is in a conduction state, a potential supplied to the wiring S1 is supplied to the gate of the transistor M2, and the emission luminance of the light-emitting device EL1 can be controlled in accordance with the potential. The transistor M3 is controlled by a signal supplied to the wiring G2. Accordingly, a potential between the transistor M2 and the light-emitting device EL1 can be reset to a constant potential supplied from the wiring V0; thus, a potential can be written to the gate of the transistor M2 in a state where a source potential of the transistor M2 is stabilized.

FIG. 15B illustrates an example of the pixel circuit PIX2 that is different from the example of the pixel circuit PIX1. The pixel circuit PIX2 has a voltage boosting function. The pixel circuit PIX2 includes a light-emitting device EL2, a transistor M4, a transistor M5, a transistor M6, a transistor M7, a capacitor C2, and a capacitor C3. Here, an example in which a light-emitting diode is used as the light-emitting device EL2 is illustrated. The pixel circuit PIX2 can be used for all the subpixels 11 (the subpixel 11R, the subpixel 11G, and the subpixel 11B) included in the pixel 10. In addition, the pixel circuit PIX2 may be used for one or two of the subpixel 11R, the subpixel 11G, and the subpixel 11B.

A gate of the transistor M4 is electrically connected to the wiring G1, one of a source and a drain of the transistor M4 is electrically connected to a wiring S4, and the other of the source and the drain of the transistor M4 is electrically connected to one electrode of the capacitor C2, one electrode of the capacitor C3, and a gate of the transistor M6. A gate of the transistor M5 is electrically connected to a wiring G3, one of a source and a drain of the transistor M5 is electrically connected to a wiring S5, and the other of the source and the drain of the transistor M5 is electrically connected to the other electrode of the capacitor C3.

One of a source and a drain of the transistor M6 is electrically connected to the wiring V2, and the other of the source and the drain of the transistor M6 is electrically connected to an anode of the light-emitting device EL2 and one of a source and a drain of the transistor M7. A gate of the transistor M7 is electrically connected to the wiring G2, and the other of the source and the drain of the transistor M7 is electrically connected to the wiring VO. A cathode of the light-emitting device EL2 is electrically connected to the wiring V1.

The transistor M4 is controlled by a signal supplied to the wiring G1, and the transistor M5 is controlled by a signal supplied to the wiring G3. The transistor M6 functions as a driving transistor that controls current flowing through the light-emitting device EL2 in accordance with a potential supplied to the gate.

The emission luminance of the light-emitting device EL2 can be controlled in accordance with the potential supplied to the gate of the transistor M6. The transistor M7 is controlled by a signal supplied to the wiring G2. A potential between the transistor M6 and the light-emitting device EL2 can be reset to a constant potential supplied from the wiring V0; thus, a potential can be written to the gate of the transistor M6 in a state where a source potential of the transistor M6 is stabilized. In addition, when the potential supplied from the wiring V0 is set to the same potential as the potential of the wiring V1 or a potential lower than that of the wiring V1, light emission of the light-emitting device EL2 can be inhibited.

The voltage boosting function of the pixel circuit PIX2 is described below.

First, a potential “D1” of the wiring S4 is supplied to the gate of the transistor M6 through the transistor M4, and at timing overlapping this, a reference potential “V_{ref}” is supplied to the other electrode of the capacitor C3 through the transistor M5. At this time, “D1−V_{ref}” is retained in the capacitor C3. Next, the gate of the transistor M6 is set to be floating, and a potential “D2”of the wiring S5 is supplied to the other electrode of the capacitor C3 through the transistor M5. Here, the potential “D2” is a potential for addition.

At this time, the potential of the gate of the transistor M6 is D1+(C₃/(C₃+C₂+C_{M6}))×(D2−V_{ref})), where the capacitance value of the capacitor C3 is C₃, the capacitance value of the capacitor C2 is C₂, and the capacitance value of the gate of the transistor M6 is C_{M6}. Here, assuming that the value of C₃ is sufficiently larger than the value of C₂+C_{M6}, C₃/(C₃+C₂+C_{M6}) approximates one. Thus, it can be said that the potential of the gate of the transistor M6 approximates “D1+(D2−V_{ref})” . Then, when D1=D2 and V_{ref}=0, “D1+(D2−V_{ref}))”=“2D1.”

That is, when the circuit is designed appropriately, a potential approximately twice as high as the potential that can be input from the wiring S4 or S5 can be supplied to the gate of the transistor M6.

Owing to such action, high voltage can be generated even using a general-purpose driver IC. Thus, voltage to be input can be decreased and power consumption can be reduced.

Alternatively, the pixel circuit PIX2 may have a structure illustrated in FIG. 15C. The pixel circuit PIX2 illustrated in FIG. 15C differs from the pixel circuit PIX2 illustrated in FIG. 15B in including a transistor M8. A gate of the transistor M8 is electrically connected to the wiring G1, one of a source and a drain of the transistor M8 is electrically connected to the other of the source and the drain of the transistor M5 and the other electrode of the capacitor C3, and the other of the source and the drain of the transistor M8 is electrically connected to the wiring V0. In addition, the one of the source and the drain of the transistor M5 is connected to the wiring S4.

As described above, in the pixel circuit PIX2 illustrated in FIG. 15B, operations of supplying the reference potential and the potential for addition to the other electrode of the capacitor C3 through the transistor M5 are performed. In this case, the two wirings S4 and S5 are necessary, and the reference potential and the potential for addition need to be rewritten alternately in the wiring S5.

In the pixel circuit PIX2 illustrated in FIG. 15C, although the transistor M8 is additionally provided, the wiring S5 can be omitted because a dedicated path for supplying the reference potential is provided. Furthermore, since the gate of the transistor M8 can be connected to the wiring G1 and the wiring VO can be used as a wiring for supplying the reference potential, a wiring connected to the transistor M8 is not additionally provided.

Moreover, alternately rewriting of the reference potential and the potential for addition is not performed in one wiring, which makes it possible to achieve high-speed operation with low power consumption.

Note that in FIG. 15B and FIG. 15C, “D1B”, an inversion potential of “D1”, may be used as the reference potential “V_{ref}.” In this case, a potential approximately three times as high as the potential that can be input from the wiring S4 or S5 can be supplied to the gate of the transistor M6. Note that the inversion potential refers to a potential such that the absolute value of the difference between the potential and a reference potential is the same (or substantially the same) as that of the difference between the original potential and the reference potential, and the potential is different from the original potential. The relationship V₀=(D1+D1B)/2 is satisfied, where the original potential is “D1,” the inversion potential is “D1B,” and the reference potential is V₀.

In the display device of this embodiment, the light-emitting device may be made to emit light in a pulsed manner to display an image. A reduction in the driving time of the light-emitting device can reduce power consumption of the display device and inhibit heat generation. An organic EL element is particularly suitable because of its excellent frequency characteristics. The frequency can be higher than or equal to 1 kHz and lower than or equal to 100 MHz, for example.

FIG. 15D illustrates an example of a pixel circuit PIX3 of the subpixel 12. The pixel circuit PIX3 includes a light-receiving device PD, a transistor M9, a transistor M10, a transistor M11, a transistor M12, and a capacitor C4. Here, an example in which a photodiode is used as the light-receiving device PD is illustrated.

A cathode of the light-receiving device PD is electrically connected to the wiring V1, and an anode of the light-receiving device PD is electrically connected to one of a source and a drain of the transistor M9. A gate of the transistor M9 is electrically connected to a wiring G4, and the other of the source and the drain of the transistor M9 is electrically connected to one electrode of the capacitor C4, one of a source and a drain of the transistor M10, and a gate of the transistor M11. A gate of the transistor M10 is electrically connected to a wiring G5, and the other of the source and the drain of the transistor M10 is electrically connected to a wiring V3. One of a source and a drain of the transistor M11 is electrically connected to a wiring V4, and the other of the source and the drain of the transistor M11 is electrically connected to one of a source and a drain of the transistor M12. A gate of the transistor M12 is electrically connected to a wiring G6, and the other of the source and the drain of the transistor M12 is electrically connected to a wiring OUT.

A constant potential is supplied to each of the wiring V1, the wiring V3, and the wiring V4. In the case where the light-receiving device PD is driven with a reverse bias, a potential lower than the potential of the wiring V1 is supplied to the wiring V3. The transistor M10 is controlled by a signal supplied to the wiring G5 and has a function of resetting the potential of a node connected to the gate of the transistor M11 to a potential supplied to the wiring V3. The transistor M9 is controlled by a signal supplied to the wiring G4 and has a function of controlling timing at which the potential of the node changes, in accordance with current flowing through the light-receiving device PD. The transistor M11 functions as an amplifier transistor that performs output corresponding to the potential of the node. The transistor M12 is controlled by a signal supplied to the wiring G6 and functions as a selection transistor for reading the output corresponding to the potential of the node by an external circuit connected to the wiring OUT.

Here, as each of the transistors M1 to M12 included in the pixel circuits PIX1 to PIX3, it is preferable to employ a transistor using a metal oxide (an oxide semiconductor) for a semiconductor layer where a channel is formed.

A transistor using a metal oxide having a wider band gap and a lower carrier density than silicon can achieve extremely low off-state current. Such low off-state current enables retention of electric charge accumulated in a capacitor that is connected in series with the transistor for a long time.

Therefore, it is preferable to use transistors employing an oxide semiconductor particularly as the transistor M1, the transistor M4, the transistor M5, the transistor M8, the transistor M9, and the transistor M10, in each of which one or the other of the source and the drain is connected to the capacitor C1, the capacitor C2, the capacitor C3, or the capacitor C4. With the use of transistors employing an oxide semiconductor in the subpixel 12, a global shutter system in which all the pixels perform the operation of accumulating electric charge at the same time can be employed without complicated circuit structures and driving methods.

Moreover, the use of transistors employing an oxide semiconductor as the other transistors can reduce manufacturing cost.

Alternatively, transistors employing silicon as a semiconductor in which a channel is formed can be used as the transistor M1 to the transistor M12. In particular, the use of silicon with high crystallinity, such as single crystal silicon or polycrystalline silicon, is preferable because high field-effect mobility is achieved and higher-speed operation is possible.

Alternatively, a structure may be employed in which a transistor employing an oxide semiconductor is used as one or more of the transistors M1 to M12 and transistors employing silicon are used as the other transistors.

Note that although FIG. 15A to FIG. 15D each illustrate an example in which n-channel transistors are used, p-channel transistors can also be used.

The transistors included in the pixel circuit PIX1, the transistors included in the pixel circuit PIX2, and the transistors included in the pixel circuit PIX3 are preferably formed side by side over the same substrate. In addition, of the wirings connected to the pixel circuits PIX1 to PIX3, wirings that are denoted by common reference numerals in FIG. 15A to FIG. 15D may be common wirings.

In addition, one or more layers including one or both of the transistor and the capacitor are preferably provided at a position overlapping the light-receiving device PD, the light-emitting device EL1, or the light-emitting device EL2. Thus, the effective occupied area of each pixel circuit can be reduced, and a high-resolution light-receiving portion or display portion can be achieved.

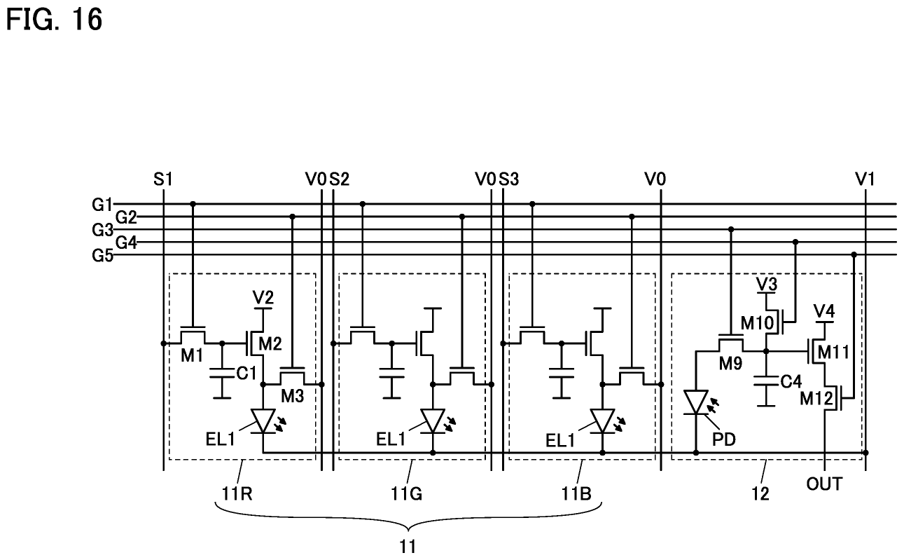

FIG. 16 is an example of a circuit diagram of the subpixel 11 (the subpixel 11R, the subpixel 11G, and the subpixel 11B) and the subpixel 12 included in the pixel 10. The wiring G1 and the wiring G2 can be electrically connected to the gate driver (FIG. 3, the circuit 16). In addition, the wiring G3 to the wiring G5 can be electrically connected to the row driver (FIG. 3, the circuit 18). The wirings S1 to S3 can be electrically connected to the source driver (FIG. 3, the circuit 15). The wiring OUT can be electrically connected to the column driver (FIG. 3, the circuit 17) and the read circuit (FIG. 3, the circuit 19).

A power supply circuit that supplies a constant potential can be electrically connected to the wirings V0 to V4, a low potential can be supplied to the wirings V0, V1, and V3, and a high potential can be supplied to the wirings V2 and V4. At this time, the wiring V3 can supply a potential lower than the potential supplied to the wiring V1.

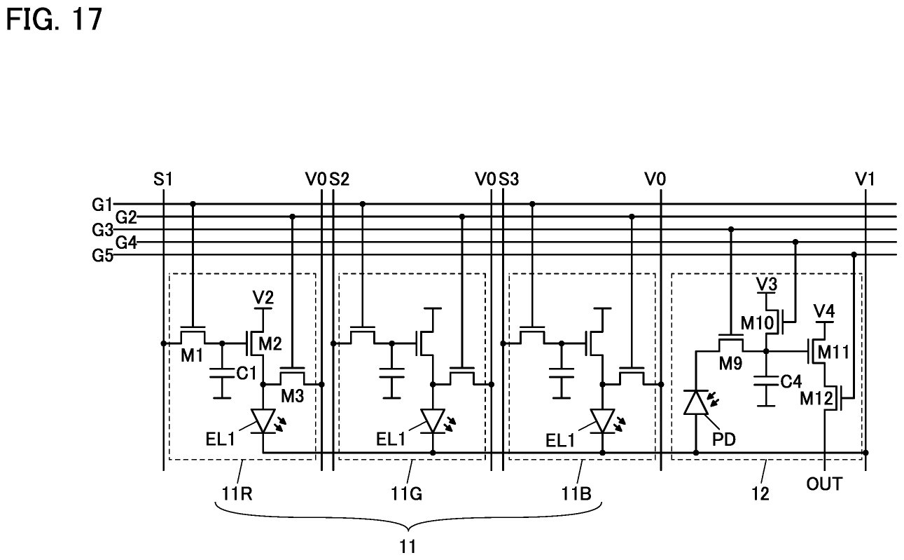

Furthermore, a structure may be employed in which the anode of the light-receiving device PD in the subpixel 12 is electrically connected to the wiring V1 and the other of the source and the drain of the transistor M10 is electrically connected to the wiring V3, as illustrated in FIG. 17. At this time, the wiring V3 can supply a potential higher than the potential supplied to the wiring V1.

In one embodiment of the present invention, a power supply line or the like can be shared by the subpixel 11 and the subpixel 12.

At least part of this embodiment can be implemented in combination with the other embodiment described in this specification as appropriate.

### [Reference Numerals]

C1: capacitor, C2: capacitor, C3: capacitor, C4: capacitor, G1: wiring, G2: wiring, G3: wiring, G4: wiring, G5: wiring, G6: wiring, M1: transistor, M2: transistor, M3: transistor, M4: transistor, M5: transistor, M6: transistor, M7: transistor, M8: transistor, M9: transistor, M10: transistor, M11: transistor, M12: transistor, PIX1: pixel circuit, PIX2: pixel circuit, PIX3: pixel circuit, S1: wiring, S3: wiring, S4: wiring, S5: wiring, V0: wiring, V1: wiring, V2: wiring, V3: wiring, V4: wiring, 10: pixel, 11: subpixel, 11B: subpixel, 11G: subpixel, 11R: subpixel, 11W: subpixel, 12: subpixel, 14: pixel array, 15: circuit, 16: circuit, 17: circuit, 18: circuit, 19: circuit, 21: light, 23c: light, 23d: reflected light, 30: electronic device, 31: display device, 32: input device, 33: input device, 41: transistor, 42: transistor, 50A: display panel, 50B: display panel, 50C: display panel, 50D: display panel, 50E: display panel, 61: display portion, 62: icon, 63: pointer, 64: housing, 65: power button, 66: button, 67: speaker, 68: microphone, 69: camera, 71: light source, 72: button, 73: communication circuit, 74: light, 81: housing, 82: antenna, 83: battery, 84: light source, 85: finger, 86: light, 87: communication circuit, 88: power feeding coil, 100A: display panel, 100B: display panel, 100C: display panel, 100D: display panel, 110: light-receiving device, 111: pixel electrode, 112: common layer, 113: photoelectric conversion layer, 114: common layer, 115: common electrode, 142: adhesive layer, 143: space, 148: light-blocking layer, 149: filter, 151: substrate, 152: substrate, 153: substrate, 154: substrate, 155: adhesive layer, 162: display portion, 164a: circuit, 164b: circuit, 165: wiring, 165a: wiring, 165b: wiring, 166: conductive layer, 172a: FPC, 172b: FPC, 173a: IC, 173b: IC, 182: buffer layer, 184: buffer layer, 190: light-emitting device, 191: pixel electrode, 192: buffer layer, 193: light-emitting layer, 194: buffer layer, 195: protective layer, 195a: inorganic insulating layer, 195b: organic insulating layer, 195c: inorganic insulating layer, 201: transistor, 204: connection portion, 205: transistor, 206: transistor, 208: transistor, 209: transistor, 210: transistor, 211: insulating layer, 212: insulating layer, 213: insulating layer, 214: insulating layer, 215: insulating layer, 216: partition, 217: partition, 218: insulating layer, 221: conductive layer, 222a: conductive layer, 222b: conductive layer, 223: conductive layer, 225: insulating layer, 228: region, 231: semiconductor layer, 231i: channel formation region, 231n: low-resistance region, and 242: connection layer.

1. An electronic device comprising a display device and an input device,
wherein the display device includes a light-emitting device and a light-receiving device in a display portion,
wherein the input device includes a light source,
wherein the display device is configured to perform display through light emission from the light-emitting device, and
wherein when light emitted from the light source is detected by the light-receiving device, the display is changed.

2. An electronic device comprising a display device and an input device,
wherein the display device includes a light-emitting device, a light-receiving device, and a first communication circuit,
wherein the input device includes a light source and a second communication circuit,
wherein the display device is configured to perform display through light emission from the light-emitting device, and
wherein the input device is in a state of being authenticated by the display device through the second communication circuit and the first communication circuit and light emitted from the light source is detected by the light-receiving device, the display is changed.

3. The electronic device according to claim 1, wherein the light-emitting device is configured to emit visible light,
wherein the light-receiving device is configured to detect infrared light, and
wherein the light source is configured to emit infrared light.

4. The electronic device according to claim 1, wherein the light-emitting device is configured to emit light of any of red, green, blue, and white.

5. The electronic device according to claim 1, wherein the light-receiving device includes a photoelectric conversion layer comprising an organic compound.

6. The electronic device according to claim 1,
wherein the light-emitting device and the light-receiving device each have a diode structure, and
wherein a cathode of the light-emitting device and an anode of the light-receiving device are electrically connected to each other.

7. The electronic device according to claim 1,
wherein the light-emitting device and the light-receiving device each have a diode structure, and
wherein a cathode of the light-emitting device and a cathode of the light-receiving device are electrically connected to each other.

8. The electronic device according to claim 1, wherein a visible-light cut-off filter is provided in a position overlapping the light-receiving device.

9. The electronic device according to claim 1, wherein the light-receiving device is capable of detecting light emitted from the light source in a position where the input device is not in contact with the display device.

10. The electronic device according to claim 1, wherein the light source is a laser.

11. The electronic device according to claim 1,
wherein the light-emitting device and the light-receiving device are electrically connected to a plurality of transistors,
wherein each of the transistors includes a metal oxide in a channel formation region, and
wherein the metal oxide include In, Zn, and M, being at least one of Al, Ti, Ga, Ge, Sn, Y, Zr, La, Ce, Nd, and Hf.

12. The electronic device according to claim 2,
wherein the light-emitting device is configured to emit visible light,
wherein the light-receiving device is configured to detect infrared light, and
wherein the light source is configured to emit infrared light.

13. The electronic device according to claim 2, wherein the light-emitting device is configured to emit light of any of red, green, blue, and white.

14. The electronic device according to claim 2, wherein the light-receiving device includes a photoelectric conversion layer comprising an organic compound.

15. The electronic device according to claim 2,
wherein the light-emitting device and the light-receiving device each have a diode structure, and
wherein a cathode of the light-emitting device and an anode of the light-receiving device are electrically connected to each other.

16. The electronic device according to claim 2,
wherein the light-emitting device and the light-receiving device each have a diode structure, and
wherein a cathode of the light-emitting device and a cathode of the light-receiving device are electrically connected to each other.

17. The electronic device according to claim 2, wherein a visible-light cut-off filter is provided in a position overlapping the light-receiving device.

18. The electronic device according to claim 2, wherein the light-receiving device is capable of detecting light emitted from the light source in a position where the input device is not in contact with the display device.

19. The electronic device according to claim 2, wherein the light source is a laser.

20. The electronic device according to claim 2,
wherein the light-emitting device and the light-receiving device are electrically connected to a plurality of transistors,
wherein each of the transistors includes a metal oxide in a channel formation region, and
wherein the metal oxide include In, Zn, and M, M being at least one of Al, Ti, Ga, Ge, Sn, Y, Zr, La, Ce, Nd, and Hf.
